(19) United States
(12) Patent Application Publication
(10) Pub. No.: US 2023/0403873 A1
(43) Pub. Date: Dec. 14, 2023

(54) ORGANIC COMPOUND AND ORGANIC LIGHT-EMITTING DEVICE

(71) Applicant: CANON KABUSHIKI KAISHA, Tokyo (JP)

(72) Inventor: TAKESHI SEKIGUCHI, Kanagawa (JP)

(21) Appl. No.: 18/330,206

(22) Filed: Jun. 6, 2023

(30) Foreign Application Priority Data
Jun. 9, 2022 (JP) 2022-093763

(51) Int. Cl. H10K 50/11; H10K 85/60; C09K 11/06; H10K 59/90

(52) U.S. Cl. CPC H10K 50/11; H10K 85/654; H10K 85/6572; C09K 11/06; H10K 59/90; C09K 2211/1018

(57) ABSTRACT

An organic compound is represented by formula (1):

Ip-L¹-Ar-L²-FL (1)

where in formula (1), Ip is an indenopyrene-containing skeleton, Ar is a heteroaryl group or a spirofluorene-containing skeleton, FL is an indenopyrene skeleton or a skeleton having a structure represented by formula (2), and L¹ and L² are each independently selected from the group consisting of a direct bond and an arylene group:

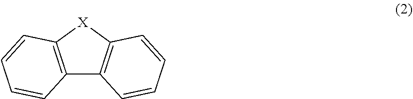

where in formula (2), X is an oxygen atom, a sulfur atom, a nitrogen atom, CR¹R², or NR³, where R¹ to R³ are each independently selected from the group consisting of a hydrogen atom, a deuterium atom, a halogen atom, an alkyl group, an aryl group, and a heteroaryl group.

### BACKGROUND OF THE INVENTION

### Field of the Invention

The present disclosure relates to an organic compound and an organic light-emitting device containing the organic compound.

### Description of the Related Art

Organic light-emitting devices (hereinafter, also referred to as “organic electroluminescent devices” or “organic EL devices”) are electronic devices each including a first electrode, a second electrode, and an organic compound layer disposed between these electrodes. The injection of electrons and holes from these pairs of electrodes generates excitons in the light-emitting organic compound in the organic compound layer, and when the excitons return to the ground state, the organic light-emitting device emits light.

Recently, organic light-emitting devices have made remarkable progress and have achieved low-driving voltage, various emission wavelengths, and fast response time. The use thereof has enabled the development of thinner and lighter light-emitting apparatuses.

To improve the performance of light-emitting devices, the development of light-emitting organic compounds with even higher performance is required and is being actively pursued.

Japanese Patent Laid-Open No. 2010-111620 (PTL 1) discloses the following compound A as a material for an organic light-emitting device that outputs light with extremely high efficiency, high luminance, and high color purity.

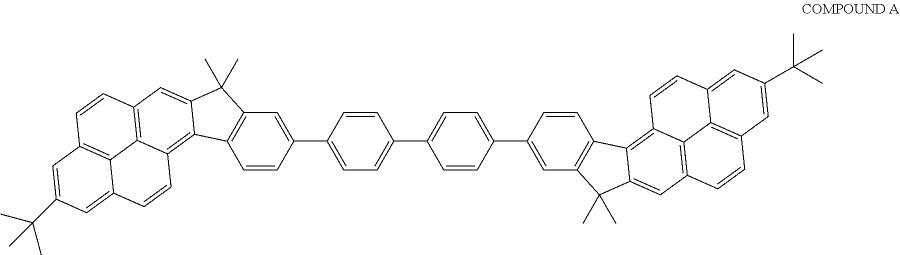 [SMILES: CC(C)(C)c1cc2ccc3cc4c(c5ccc(c1)c2c35)-c1ccc(-c2ccc(-c3ccc(-c5ccc6c(c5)C(C)(C)c5cc7ccc8cc(C(C)(C)C)cc9ccc(c5-6)c7c89)cc3)cc2)cc1C4(C)C]

Compound A described in PTL 1 above, however, has a linking group that connects the two indenopyrene moieties and that is a highly planar biphenyl group, thereby leading to insufficient sublimability and solubility of the compound. For this reason, the compound had poor light emission characteristics. Thus, compound A described in PTL 1 has room for improvement in light emission characteristics.

### SUMMARY OF THE INVENTION

The present disclosure has been made in light of the foregoing disadvantages and provides an organic compound excellent in light emission characteristics.

The organic compound according to an embodiment of the present disclosure is represented by formula (1):

Ip-L¹-Ar-L²-FL (1)

where in formula (1), Ip is an indenopyrene-containing skeleton, Ar is a substituted or unsubstituted heteroaryl group or a spirofluorene-containing skeleton, and FL is an indenopyrene skeleton or a skeleton having a structure represented by formula (2), and L¹ and L² are each independently selected from the group consisting of a direct bond and a substituted or unsubstituted arylene group:

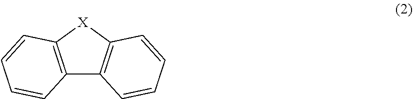

where in formula (2), X is an oxygen atom, a sulfur atom, a nitrogen atom, CR¹R², or NR³, where R¹ to R³ are each independently selected from the group consisting of a hydrogen atom, a deuterium atom, a halogen atom, a substituted or unsubstituted alkyl group, a substituted or unsubstituted aryl group, and a substituted or unsubstituted heteroaryl group.

Further features of the present disclosure will become apparent from the following description of exemplary embodiments with reference to the attached drawings.

### BRIEF DESCRIPTION OF THE DRAWINGS

FIG. 1A is a schematic cross-sectional view of an example of a pixel of a display apparatus according to an embodiment of the present disclosure, and FIG. 1B is a schematic cross-sectional view of an example of a display apparatus including organic light-emitting devices according to an embodiment of the present disclosure.

FIG. 2 is a schematic view of an example of a display apparatus according to an embodiment of the present disclosure.

FIG. 3A is a schematic view of an example of an image pickup apparatus according to an embodiment of the present disclosure, and FIG. 3B is a schematic view of an example of an electronic apparatus according to an embodiment of the present disclosure.

FIG. 4A is a schematic view of an example of a display apparatus according to an embodiment of the present disclosure, and FIG. 4B is a schematic view of an example of a foldable display apparatus.

FIG. 5A is a schematic view of an example of a lighting apparatus according to an embodiment of the present disclosure, and FIG. 5B is a schematic view of an example of an automobile including an automotive lighting unit according to an embodiment of the present disclosure.

FIG. 6A is a schematic view illustrating an example of a wearable device according to an embodiment of the present disclosure, and FIG. 6B is a schematic view of an example of a wearable device according to an embodiment of the present disclosure, the wearable device including an image pickup apparatus.

FIG. 7A is a schematic view of an example of an image-forming apparatus according to an embodiment of the present disclosure, FIG. 7B is a schematic view of an example of an exposure light source of an image-forming apparatus according to an embodiment of the present disclosure, and FIG. 7C is a schematic view of an example of an exposure light source of an image-forming apparatus according to an embodiment of the present disclosure.

FIG. 8A illustrates the normalized EL spectrum of compound (1), and FIG. 8B illustrates normalized EL spectra of compound (25), compound (29), and compound A.

### DESCRIPTION OF THE EMBODIMENTS

An alkyl group used in this specification may be an alkyl group having 1 to 20 carbon atoms. Non-limiting examples of the alkyl group include a methyl group, an ethyl group, a n-propyl group, an isopropyl group, a n-butyl group, a tert-butyl group, a sec-butyl group, an octyl group, a cyclohexyl group, a tert-pentyl group, a 3-methylpentan-3-yl group, a 1-adamantyl group, and a 2-adamantyl group.

An aryl group may be an aryl group having 6 to 20 carbon atoms. Non-limiting examples of the aryl group include a phenyl group, a naphthyl group, an indenyl group, a biphenyl group, a terphenyl group, a fluorenyl group, a phenanthryl group, a triphenylenyl group, a pyrenyl group, an anthryl group, a perylenyl group, a chrysenyl group, and a fluoranthenyl group.

A heteroaryl group may be a heteroaryl group having 3 to 24 carbon atoms. Non-limiting examples of the heteroaryl group include a pyridyl group, a pyrimidinyl group, a pyrazinyl group, a triazinyl group, a benzofuranyl group, a benzothiophenyl group, a dibenzofuranyl group, a dibenzothiophenyl group, an oxazolyl group, an oxadiazolyl group, a thiazolyl group, a thiadiazolyl group, a carbazolyl group, an acridinyl group, and a phenanthrolinyl group.

Non-limiting examples of substituents that may be further contained in the alkyl group, the aryl group, and the heteroaryl group include alkyl groups, such as a methyl group, an ethyl group, a n-propyl group, an isopropyl group, a n-butyl group, and a tert-butyl group; aralkyl groups, such as a benzyl group; aryl groups, such as a phenyl group and a biphenyl group; heteroaryl groups, such as a pyridyl group and a pyrrolyl group; amino groups, such as a dimethylamino group, a diethylamino group, a dibenzylamino group, a diphenylamino group, and a ditolylamino group; alkoxy groups, such as a methoxy group, an ethoxy group, and a propoxy group; aryloxy groups, such as a phenoxy group; halogen atoms, such as a fluorine atom, a chlorine atom, a bromine atom, and an iodine atom; a deuterium atom; and a cyano group.

### (1) Organic Compound

An organic compound according to an embodiment of the present disclosure will be described.

The organic compound according to an embodiment of the present disclosure is represented by formula (1).

Ip-L¹-Ar-L²-FL (1)

In formula (1), Ip is an indenopyrene-containing skeleton. Ip may contain, as a substituent, a deuterium atom, a halogen atom, a substituted or unsubstituted alkyl group, a substituted or unsubstituted aryl group, or a substituted or unsubstituted heteroaryl group. Specifically, the substituent can be an alkyl group having 1 to 4 carbon atoms, or can be a methyl group or a tert-butyl group. This is because the substituent is bulkier than a hydrogen atom, and the presence of the substituent can further inhibit molecular aggregation. Among indenopyrene skeletons, in particular, Ip can contain a 7H-indeno[1,2-a]pyrene skeleton. The 7H-indeno[1,2-a]pyrene skeleton has particularly high oscillator strength among indenopyrene skeletons and thus can provide higher luminous efficiency. When Ip is the 7H-indeno[1,2-a]pyrene skeleton, Ip can have a substituent at the 2-position of the skeleton. When Ip is the 7H-indeno[1,2-a]pyrene skeleton, Ip can be bonded to Ar at the 9-position of 7H-indeno[1,2-a]pyrene.

The reason for this is that the bonding of Ip to Ar at the 9-position (the numbers in the structural formula below indicate the substitution positions of 7H-indeno[1,2-a]pyrene) of 7H-indeno[1,2-a]pyrene improves the oscillator strength of the skeleton and the luminous efficiency.

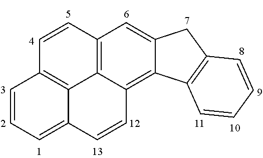

In formula (1), Ar is a substituted or unsubstituted heteroaryl group or a

spirofluorene-containing skeleton. Ar may further contain a deuterium atom, a halogen atom, a substituted or unsubstituted alkyl group, a substituted or unsubstituted aryl group, or a substituted or unsubstituted heteroaryl group. Specifically, Ar can contain an alkyl group having 1 to 4 carbon atoms or can contain a tert-butyl group,

When Ar is a substituted or unsubstituted heteroaryl group, the heteroaryl group can be a heteroaryl group having a nitrogen atom as a heteroatom. Specifically, the heteroaryl group can contain at least one skeleton selected from the group consisting of a pyridine skeleton, a pyrimidine skeleton, a pyrazine skeleton, a pyridazine skeleton, a triazine skeleton, a quinoline skeleton, an isoquinoline skeleton, and a naphthyridine skeleton, or can contain at least one skeleton selected from the group consisting of a pyridine skeleton, a pyrimidine skeleton, and a triazine skeleton. This is because the pyridine skeleton, the pyrimidine skeleton, and the triazine skeleton are excellent in chemical stability even at high temperatures. The skeleton can also be used from the viewpoint of enabling the emission of blue light with excellent color purity due to a particularly short conjugation length of the skeleton. When Ar is a pyridine skeleton, a pyrimidine skeleton, a pyrazine skeleton, a pyridazine skeleton, or a triazine skeleton, Ar can be bonded to Ip and FL at the meta-positions of the skeleton. This is because the bonding of Ar to Ip and FL at the meta-positions of Ar can result in a short conjugation length to provide the emission of blue light with excellent color purity.

When Ar is a spirofluorene-containing skeleton, specific examples thereof can include 9,9′-spirobifluorene, spiro[7H-benzo[c]fluorene-7,9′-[9H]fluorene], spiro[9H-fluorene-9,9′-[9H]indeno[2,1-c]phenanthrene]spiro[13H-dibenzo[a,i]fluorene-13,9′-[9H]fluorene], spiro[4H-cyclopenta[def]phenanthrene-4,9′-[9H]fluorene], and spiro[fluorene-9,7′-fluoreno[4,3-b]benzofran].

Among these, in particular, 9,9′-spirobifluorene skeleton can be used. This is because the 9,9′-spirobifluorene skeleton has a particularly short conjugation length and thus can emit blue light with excellent color purity. When Ar is a 9,9′-spirobifluorene skeleton, Ar can be bonded to Ip and FL at the 2- and 7-positions or at the 2′- and 7′-positions (the numbers in the structural formula on the left below indicate the substitution positions of 9,9′-spirobifluorene) of 9,9′-spirobifluorene. This is because fluorene is bonded to Ip and FL at the 2- and 7-positions (the numbers in the structural formula on the right side below indicate the substitution positions of fluorene) to improve the oscillator strength and the luminous efficiency.

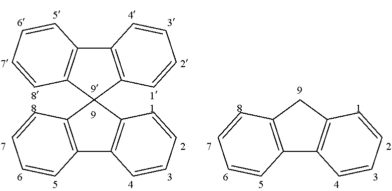

In formula (1), FL is an indenopyrene skeleton or a skeleton having a structure represented by formula (2). In particular, FL can contain an indenopyrene skeleton, a fluorene skeleton, a dibenzofuran skeleton, a dibenzothiophene skeleton, or a carbazole skeleton. This is because the indenopyrene skeleton and the fluorene skeleton have high oscillator strength and excellent luminous efficiency. When FL contains a dibenzofuran skeleton, a dibenzothiophene skeleton, or a carbazole skeleton, the abundant lone pairs of oxygen atoms, sulfur atoms, or nitrogen atoms contained in the skeletons can improve the charge transport properties. Thus, the use of the compound can easily adjust the carrier balance. In particular, from the viewpoint of improving luminous efficiency, FL can contain an indenopyrene skeleton or a fluorene skeleton, or can be a 7H-indeno[1,2-a]pyrene skeleton.

FL may contain, as a substituent, a deuterium atom, a halogen atom, a substituted or unsubstituted alkyl group, a substituted or unsubstituted aryl group, or a substituted or unsubstituted heteroaryl group. Specifically, the substituent may be an alkyl group having 1 to 4 carbon atoms, or may be a tert-butyl group.

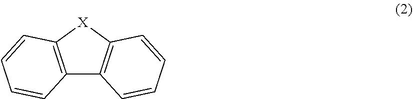

In formula (2), X is an oxygen atom, a sulfur atom, a nitrogen atom, CR¹R², or NR³, where R¹ to R³ are each independently selected from the group consisting of a hydrogen atom, a deuterium atom, a halogen atom, a substituted or unsubstituted alkyl group, a substituted or unsubstituted aryl group, and a substituted or unsubstituted heteroaryl group. Each of R¹ to R³ can be an alkyl group having 1 to 4 carbon atoms or an aryl group having 6 to 10 carbon atoms, or can be a methyl group. This is because the substituent is bulkier than a hydrogen atom, and the presence of the substituent can inhibit molecular aggregation.

In formula (1), L¹ and L² are each independently selected from the group consisting of a direct bond and a substituted or unsubstituted arylene group. L¹ and L² can each be independently selected from the group consisting of a direct bond and a phenylene group.

When the organic compound according to an embodiment of the present disclosure contains a deuterium atom, the organic compound has excellent durability. Accordingly, when the organic compound according to an embodiment of the present disclosure is used in an organic light-emitting device, it is possible to provide an organic light-emitting device having an excellent device lifetime.

The organic compound represented by formula (1) has the following features.
(1-1) Sublimability is excellent when Ar is a substituted or unsubstituted heteroaryl group.
(1-2) Solubility is excellent when Ar is a spirofluorene-containing skeleton.

These features will be described below.
(1-1) Sublimability is excellent when Ar is a substituted or unsubstituted heteroaryl group.

The inventors have conducted intensive studies and have found that an organic compound according to an embodiment of the present disclosure has excellent sublimability when Ar is a substituted or unsubstituted heteroaryl group.

In compound A described in PTL 1, a biphenylene group is used as a linking group that connects two indenopyrene skeletons. The biphenylene group is an aromatic hydrocarbon compound group, and has a highly planar structure and thus easily causes intermolecular stacking. For this reason, the sublimation temperature tends to be high.

In contrast, in the organic compound represented by formula (1), Ar is a substituted or unsubstituted heteroaryl group. This can result in the nonuniform distribution of the electron density or polarizability of Ar to reduce the intermolecular interaction, thereby inhibiting intermolecular stacking.

As described above, the organic compound according to an embodiment of the present disclosure is an organic compound having a low sublimation temperature when Ar is a substituted or unsubstituted heteroaryl group. In other words, the organic compound can be said to be an organic compound having excellent sublimability.
(1-2) Solubility is excellent when Ar is a spirofluorene-containing skeleton.

The inventors have further conducted intensive studies and have found that an organic compound according to an embodiment of the present disclosure has excellent solubility when Ar is a spirofluorene-containing skeleton.

In the organic compound represented by formula (1), Ar is a spirofluorene-containing skeleton. This enables the organic compound to have a higher solubility than compound A containing the biphenylene group.

As described above, the organic compound in which Ar is a spirofluorene-containing skeleton in formula (1) is an organic compound having excellent solubility.

Specific examples of the organic compound according to an embodiment of the present disclosure are illustrated below. However, the invention is not limited thereto.

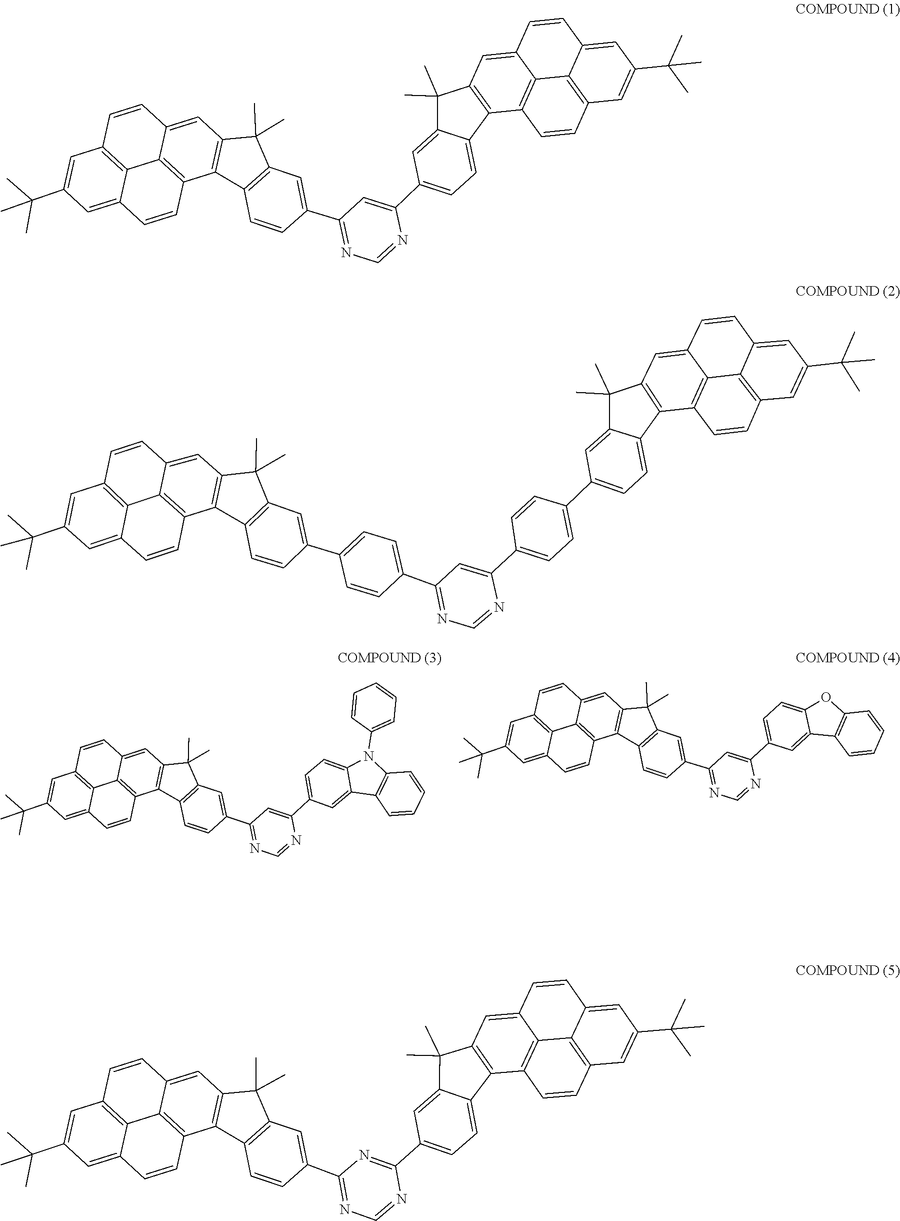

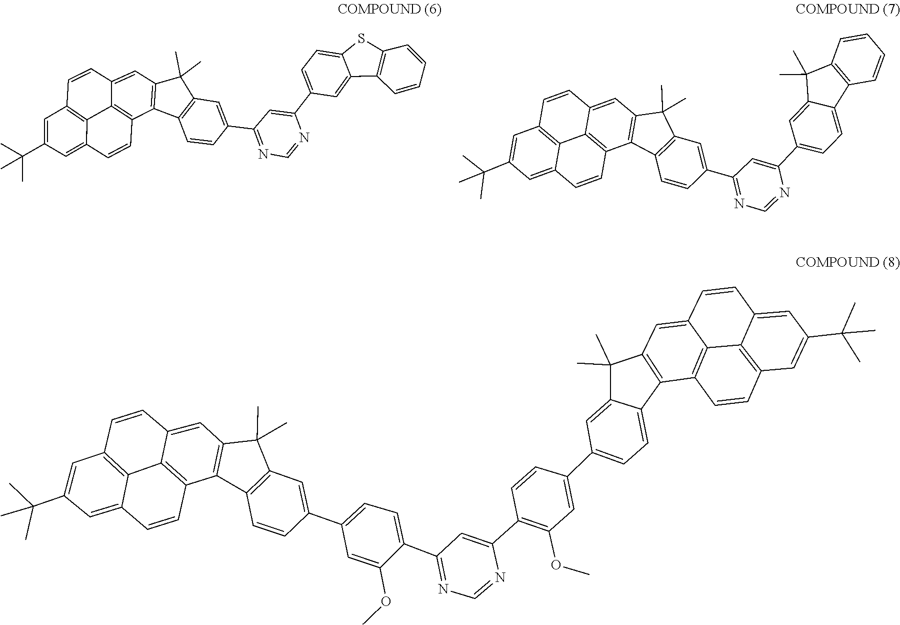 [SMILES: CC(C)(C)c1cc2ccc3cc4c(c5ccc(c1)c2c35)-c1ccc(-c2cc(-c3ccc5sc6ccccc6c5c3)ncn2)cc1C4(C)C ; CC(C)(C)c1cc2ccc3cc4c(c5ccc(c1)c2c35)-c1ccc(-c2cc(-c3ccc5c(c3)C(C)(C)c3ccccc3-5)ncn2)cc1C4(C)C ; COc1cc(-c2ccc3c(c2)C(C)(C)c2cc4ccc5cc(C(C)(C)C)cc6ccc(c2-3)c4c56)ccc1-c1cc(-c2ccc(-c3ccc4c(c3)C(C)(C)c3cc5ccc6cc(C(C)(C)C)cc7ccc(c3-4)c5c67)cc2OC)ncn1]

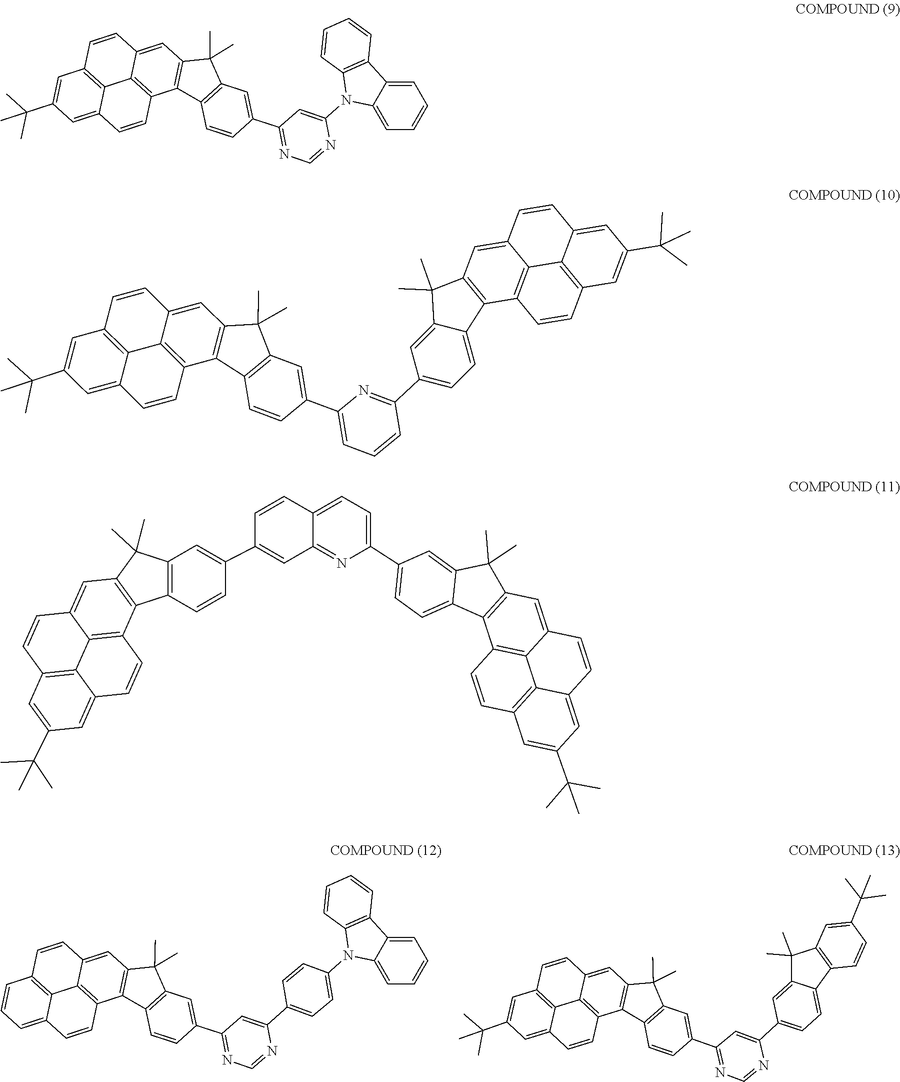

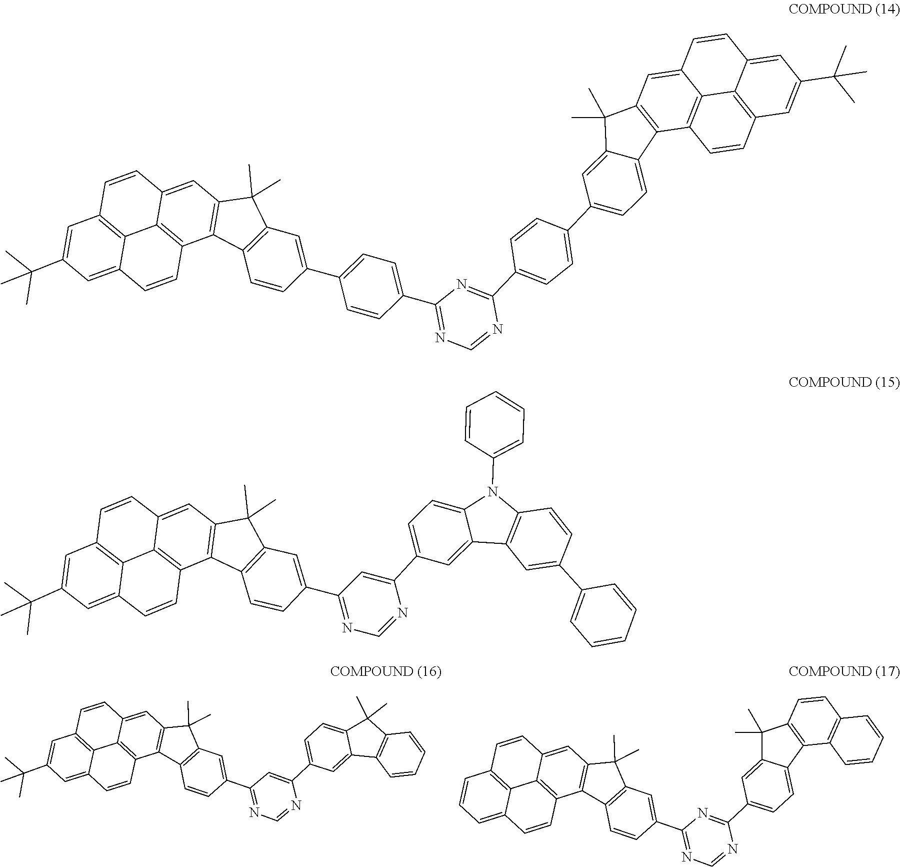

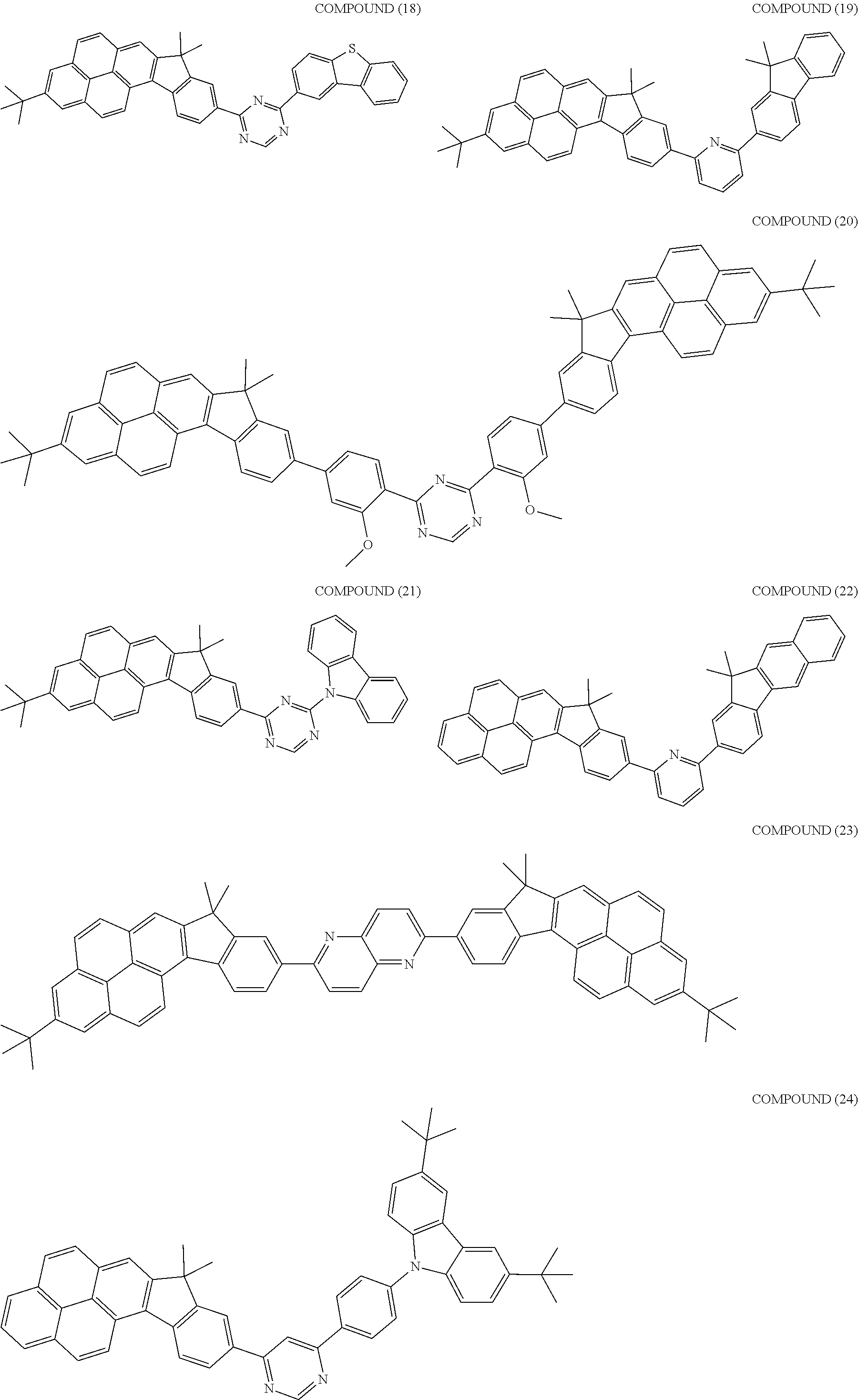

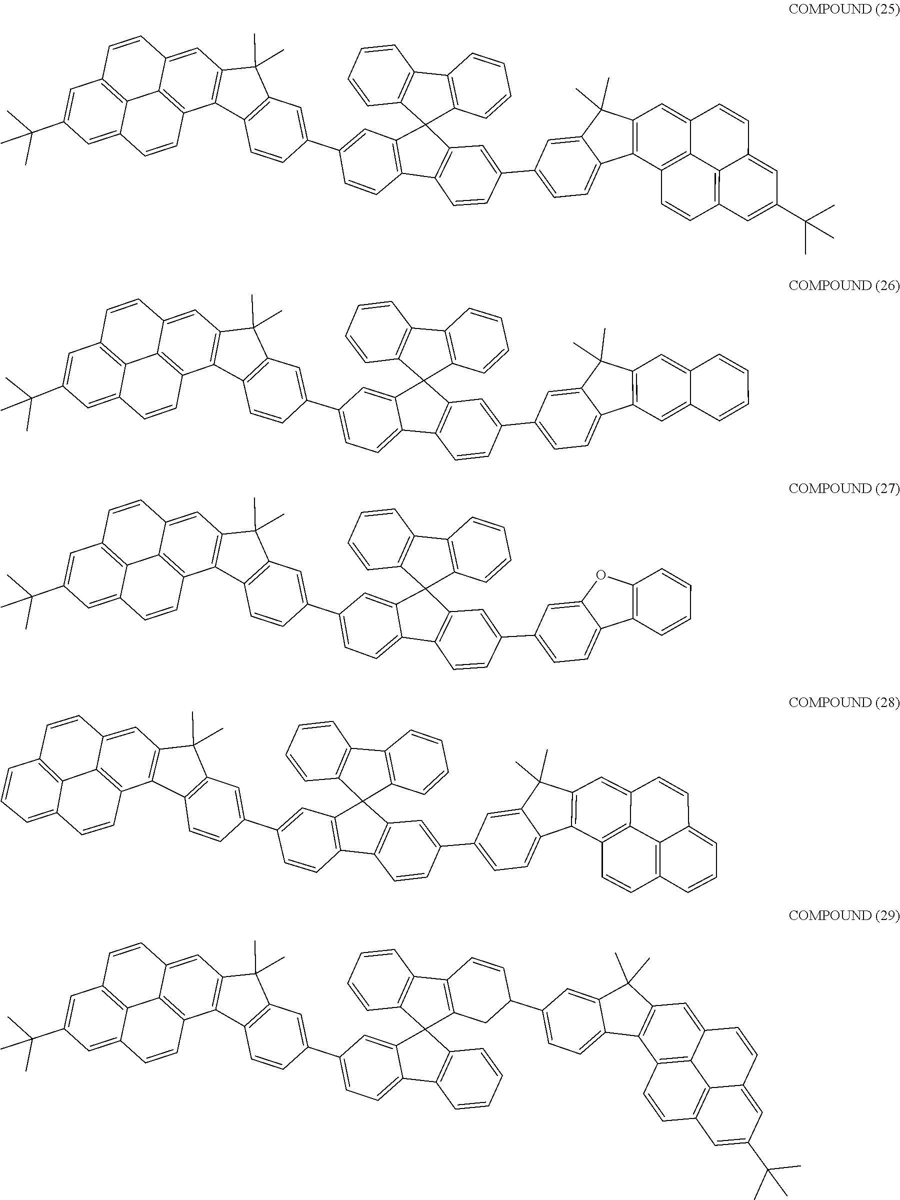

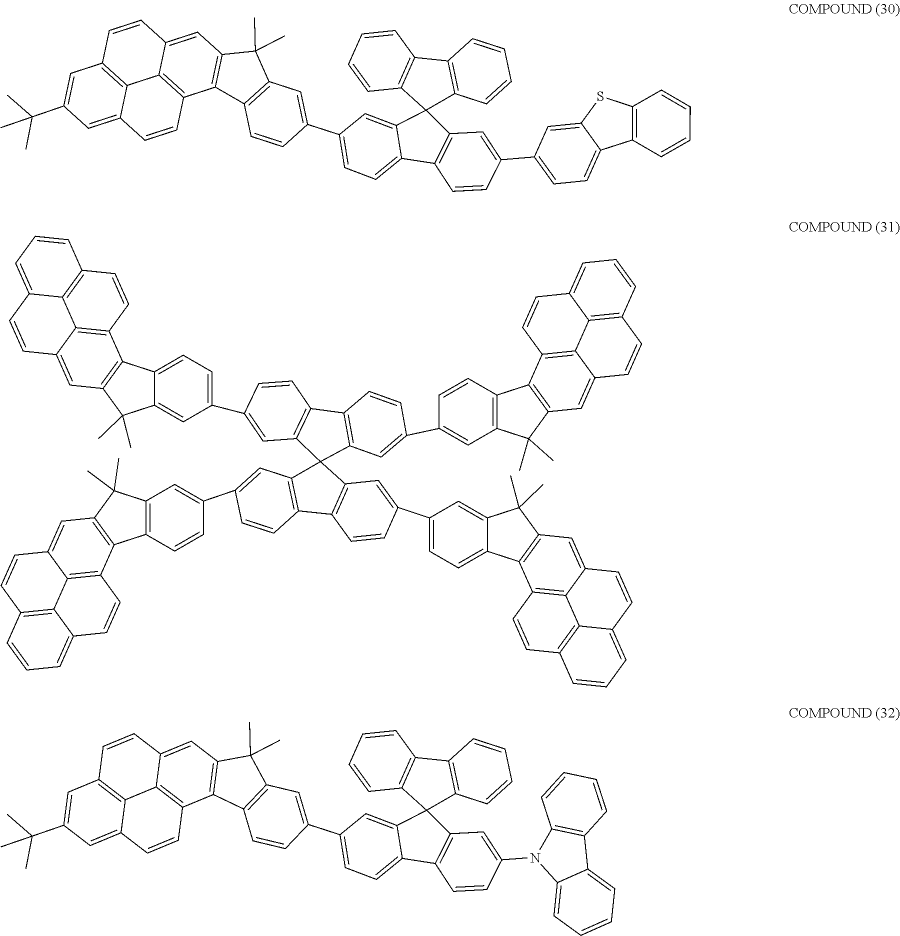

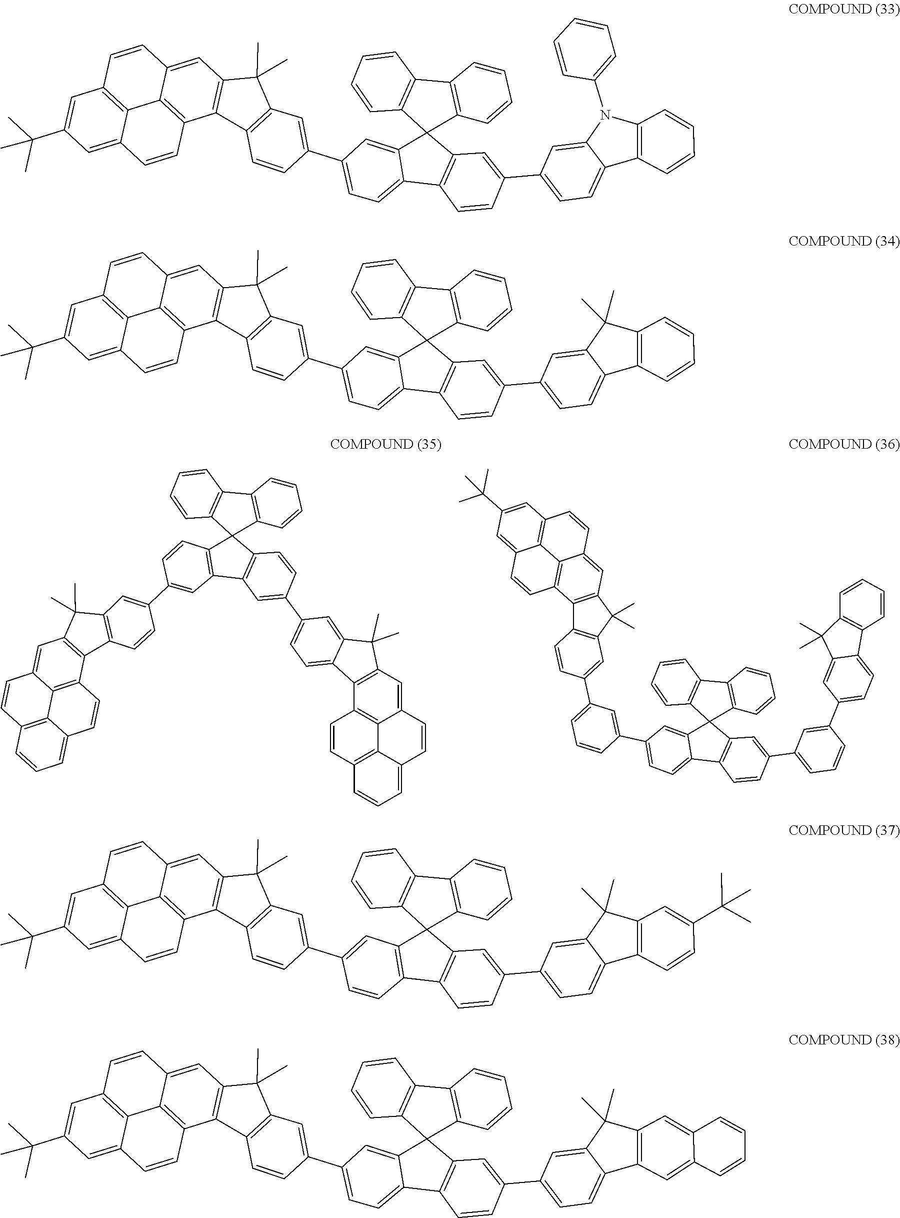

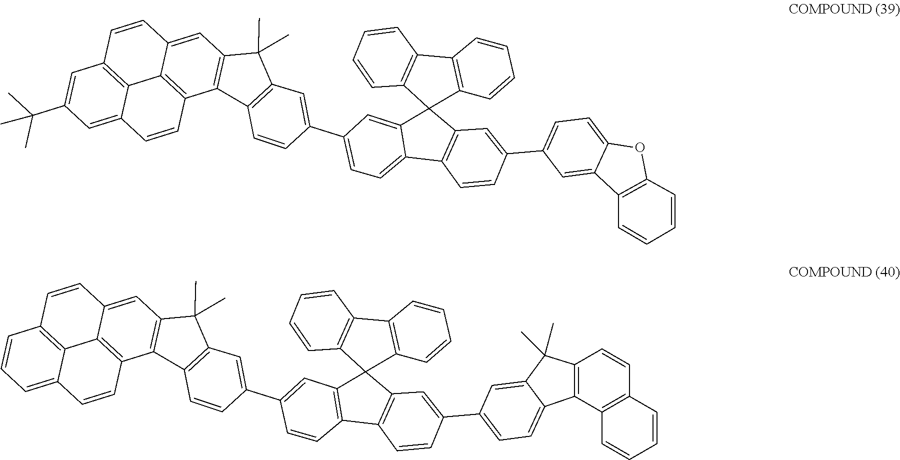

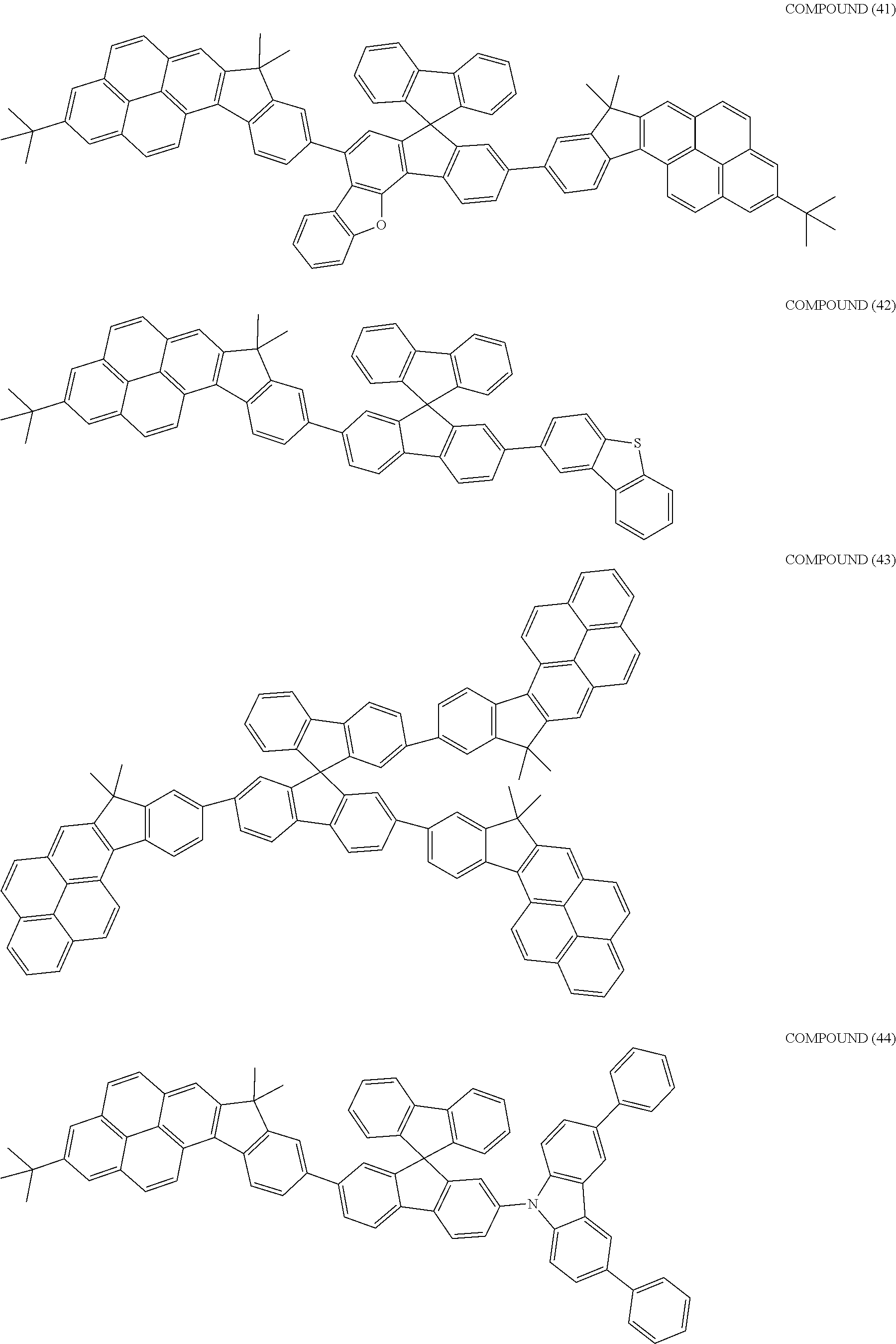

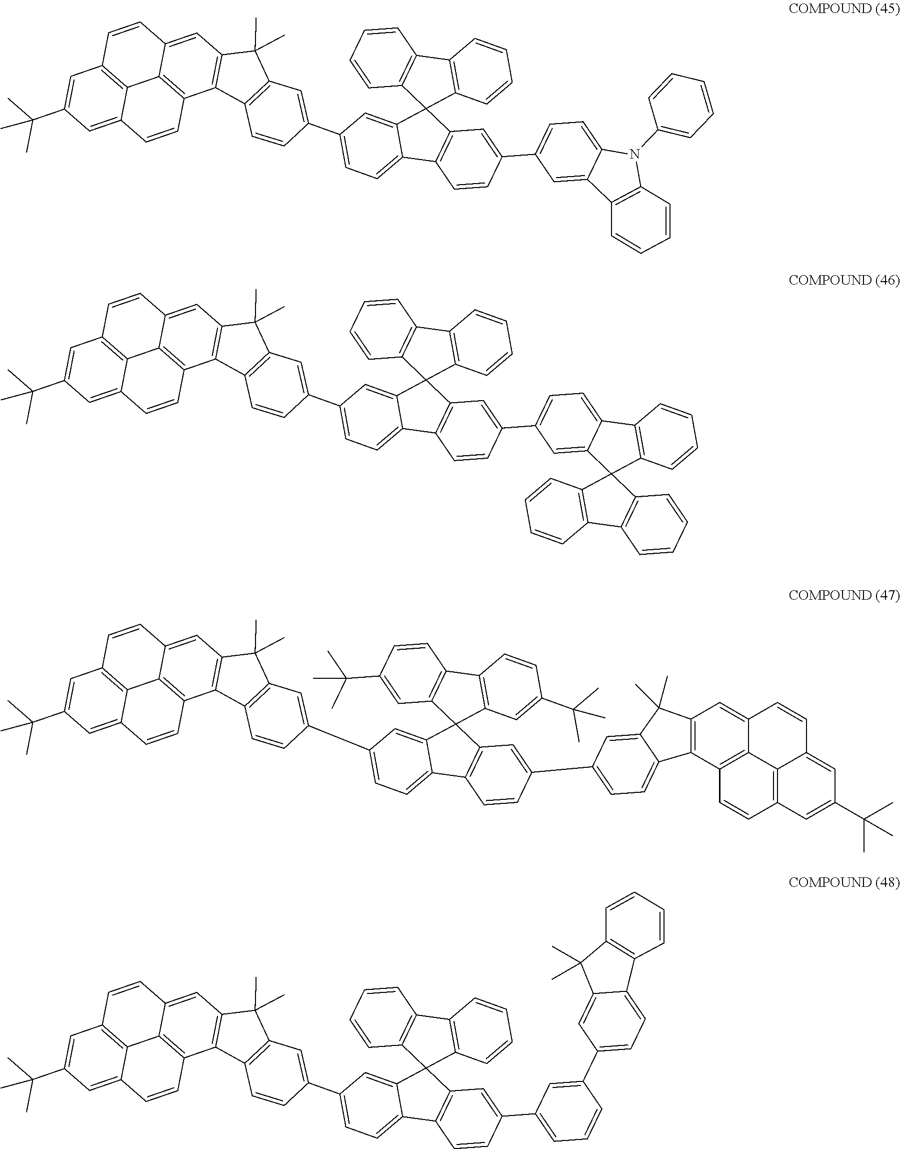

Among the above-exemplified compounds, compounds (1) to (24) are organic compounds each containing Ar that is a substituted or unsubstituted heteroaryl group. Thus, they are organic compounds particularly excellent in sublimability.

Among the above-exemplified compounds, compounds (25) to (48) are organic compounds each containing Ar that is a spirofluorene skeleton. Thus, they are organic compounds particularly excellent in solubility.

### (2) Organic Light-Emitting Device

The organic light-emitting device according to an embodiment will be described below. The organic light-emitting device according to the present embodiment includes at least a first electrode, a second electrode, and an organic compound layer disposed between these electrodes.

One of the first electrode and the second electrode may be an anode, and the other may be a cathode. In the organic light-emitting device according to the present embodiment, the organic compound layer may be formed of a single layer or a laminate including multiple layers, as long as it includes a light-emitting layer. When the organic compound layer is formed of a laminate including multiple layers, the organic compound layer may include, in addition to the light-emitting layer, a hole injection layer, a hole transport layer, an electron-blocking layer, a hole-exciton-blocking layer, an electron transport layer, and an electron injection layer, for example. The light-emitting layer may be formed of a single layer or a laminate including multiple layers.

In the organic light-emitting device according to the present embodiment, at least one layer in the organic compound layer contains the organic compound according to the present embodiment. Specifically, the organic compound according to the present embodiment is contained in any of the light-emitting layer, the hole injection layer, the hole transport layer, the electron-blocking layer, the hole-exciton-blocking layer, the electron transport layer, the electron injection layer, and so forth described above. The organic compound according to the present embodiment can be contained in the light-emitting layer.

In the organic light-emitting device according to the embodiment, when the organic compound according to the embodiment is contained in the light-emitting layer, the light-emitting layer may consist of only the organic compound according to the embodiment or may be composed of the organic compound according to the embodiment and another compound. When the light-emitting layer is composed of the organic compound according to the embodiment and another compound, the organic compound according to the embodiment may be used as a host or a guest in the light-emitting layer. The organic compound may be used as an assist material that can be contained in the light-emitting layer. The term “host” used here refers to a compound having the highest proportion by mass in compounds contained in the light-emitting layer. The term “guest” refers to a compound that has a lower proportion by mass than the host in the compounds contained in the light-emitting layer and that is responsible for main light emission. The term “assist material” refers to a compound that has a lower proportion by mass than the host in the compounds contained in the light-emitting layer and that assists the light emission of the guest. The assist material is also referred to as a “second host”. The host material may also be referred to as a “first compound”, and the assist material may also be referred to as a “second compound”.

When the organic compound according to the present embodiment is used as a guest in the light-emitting layer, the concentration of the guest is preferably 0.01% or more by mass and 20% or less by mass, more preferably 0.01% or more by mass and 5.0% or less by mass, based on the entire light-emitting layer.

The inventors have conducted various studies and have found that when the organic compound according to the present embodiment is used as a host or guest of a light-emitting layer, especially as a guest of a light-emitting layer, a device that emits light with high efficiency and high luminance, and that is highly durable is provided. This light-emitting layer can be formed of a single layer or multiple layers and can also contain a light-emitting material having another emission color in order to conduct the color mixture of the blue emission color of the present embodiment and another emission color. The term “multiple layers” refers to a state in which a light-emitting layer and another light-emitting layer are stacked. In this case, the emission color of the organic light-emitting device is not limited to blue. More specifically, the emission color may be white or an intermediate color. In the case of white, another light-emitting layer emits light of a color other than blue, that is, red or green.

A film-forming method is vapor deposition or coating. Details will be described in Examples below.

The organic compound according to the present embodiment can be used as a component material of an organic compound layer other than the light-emitting layer included in the organic light-emitting device according to the embodiment. Specifically, the organic compound may be used as a component material of the electron transport layer, the electron injection layer, the hole transport layer, the hole injection layer, the hole-blocking layer, and so forth. In this case, the emission color of the organic light-emitting device is not limited to blue. More specifically, the emission color may be white or intermediate color.

For example, a hole injection compound, a hole transport compound, a host compound, a light-emitting compound, an electron injection compound, or an electron transport compound, which is known and has a low or high molecular weight, can be used together with the organic compound according to the present embodiment, as needed. Examples of these compounds are illustrated below.

As a hole injection-transport material, a material having a high hole mobility can be used so as to facilitate the injection of holes from the anode and to transport the injected holes to the light-emitting layer. To reduce a deterioration in film quality, such as crystallization, in the organic light-emitting device, a material having a high glass transition temperature can be used. Examples of a low- or high-molecular-weight material having the ability to inject and transport holes include triarylamine derivatives, aryl carbazole derivatives, phenylenediamine derivatives, stilbene derivatives, phthalocyanine derivatives, porphyrin derivatives, poly(vinyl carbazole), polythiophene, and other conductive polymers. Moreover, the hole injection-transport material can also be used for the electron-blocking layer. In the case of using a coating method, a mixture (PEDOT:PSS) of poly(ethylenedioxythiophene) and poly(styrene sulfonate), which is typically used as a hole injection material, may be used. Non-limiting specific examples of a compound used as the hole injection-transport material will be illustrated below.

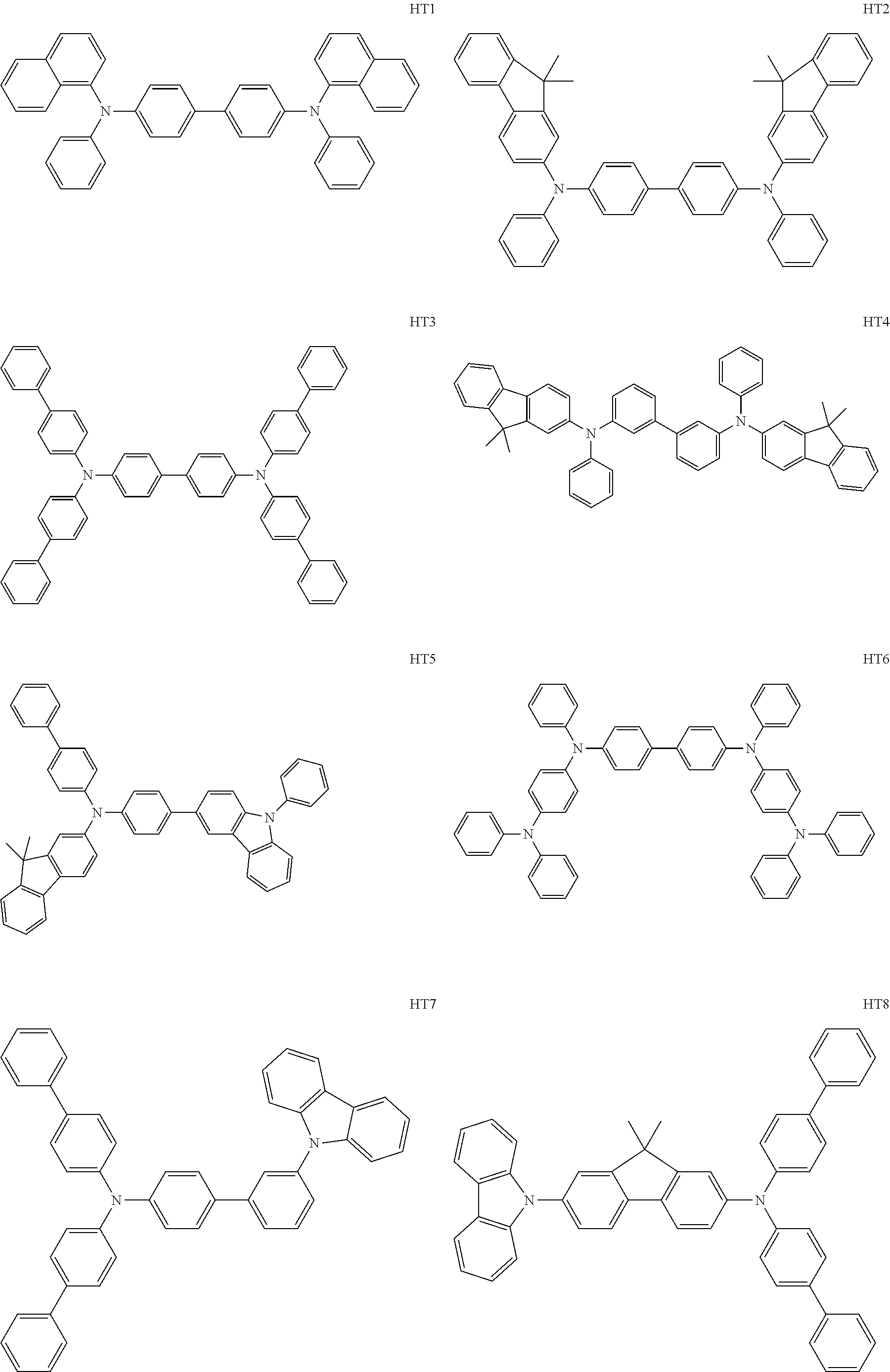

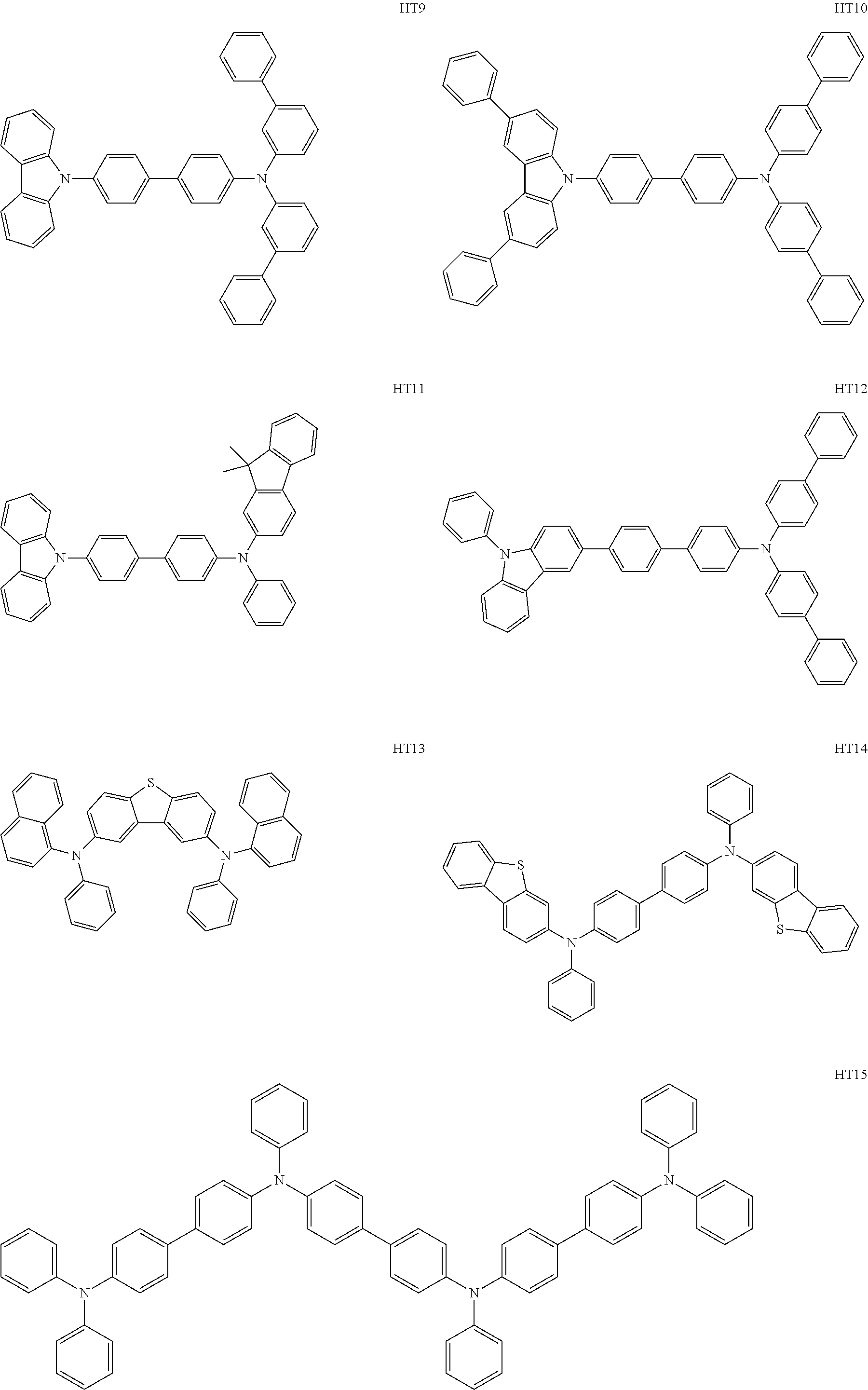

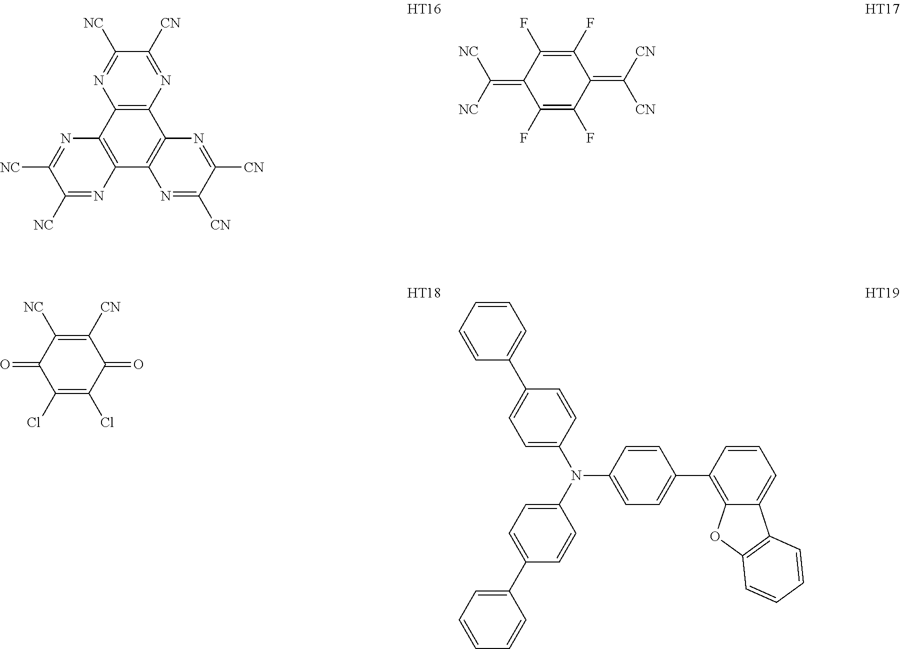 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F ; N#CC1=C(C#N)C(=O)C(Cl)=C(Cl)C1=O ; c1ccc(-c2ccc(N(c3ccc(-c4ccccc4)cc3)c3ccc(-c4cccc5c4oc4ccccc45)cc3)cc2)cc1]

Among the hole transport materials illustrated above, HT16 to HT18 can be used in the layer in contact with the anode to reduce the driving voltage. HT16 is widely used for organic light-emitting devices. HT2, HT3, HT4, HT5, HT6, HT7, HT10, and HT12 may be used in an organic compound layer adjacent to HT16. Polymer compounds, such as hole-transporting poly(phenylene vinylene) (PPV), polyfluorene (PF), polyvinylcarbazole (PVK), and derivatives thereof, may also be used. In addition to this, it is also possible to use, for example, inorganic insulating materials, such as SiO2 and SiN, and organic silicon polymers, such as siloxane. Multiple materials may be used in a single organic compound layer.

Examples of a light-emitting material mainly associated with a light-emitting function include fused-ring compounds, such as fluorene derivatives, naphthalene derivatives, pyrene derivatives, perylene derivatives, tetracene derivatives, anthracene compounds, and rubrene, quinacridone derivatives, coumarin derivatives, stilbene derivatives, organoaluminum complexes, such as tris(8-quinolinolato)aluminum, iridium complexes, platinum complexes, rhenium complexes, copper complexes, europium complexes, ruthenium complexes, and polymer derivatives, such as poly(phenylene vinylene) derivatives, polyfluorene derivatives, and polyphenylene derivatives. When the light-emitting layer is produced by a coating method, a light-emitting polymer compound is mainly used. This is because polymer compounds are highly amorphous and are less likely to crystallize than low-molecular-weight compounds. Specific examples of a material used include polymer compounds, such as poly(phenylene vinylene) (PPV), polyfluorene (PF), polyvinylcarbazole (PVK), and derivatives thereof.

Non-limiting specific examples of a compound used as a light-emitting material are described below.

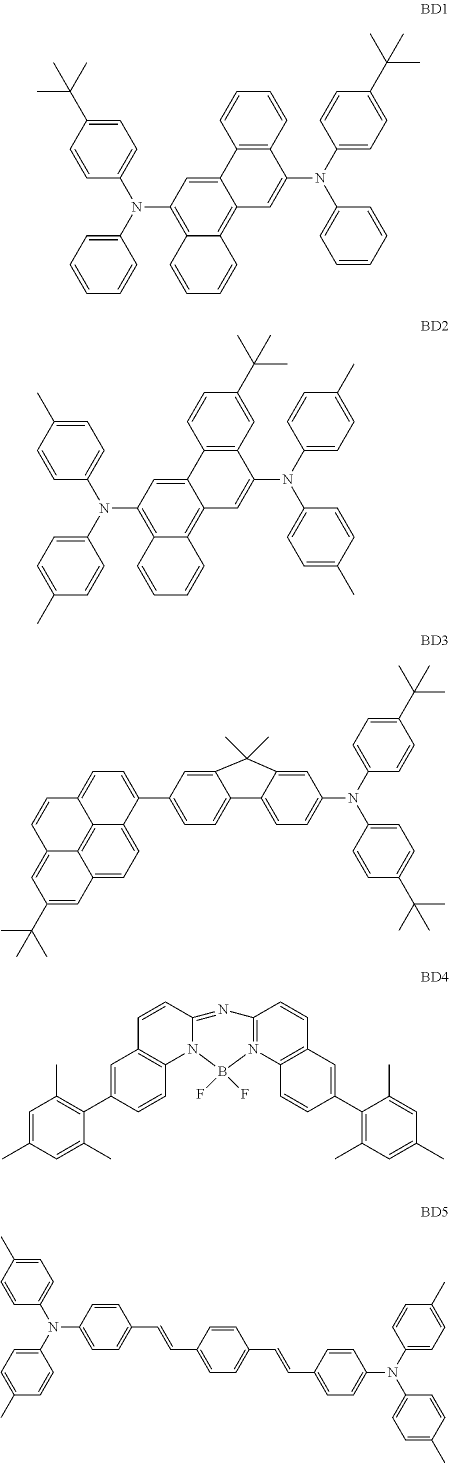

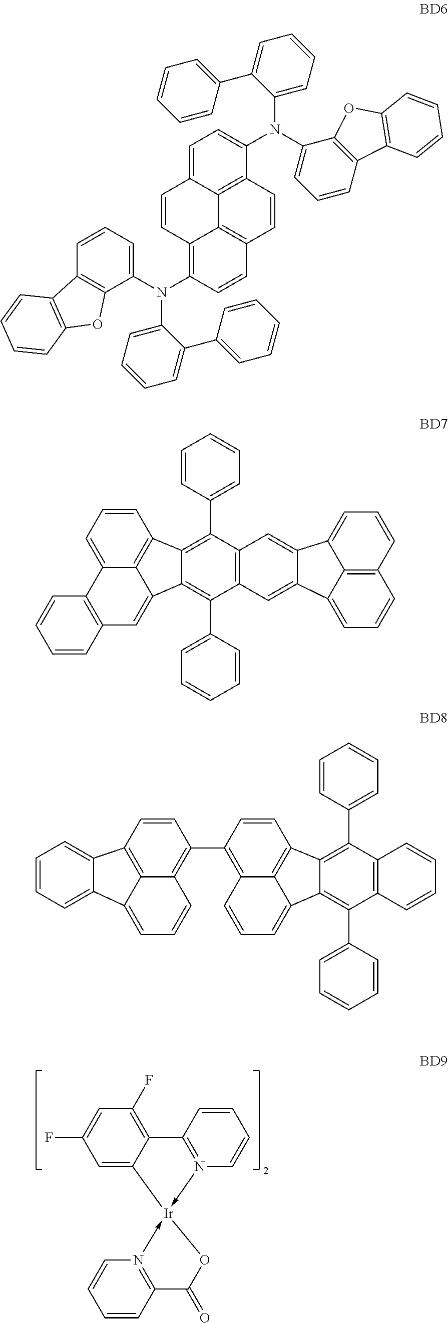

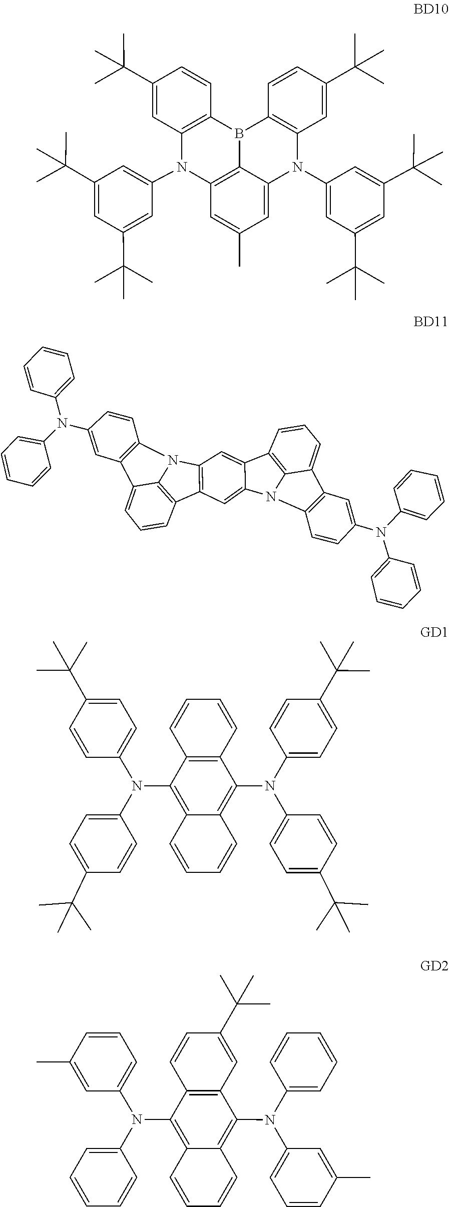

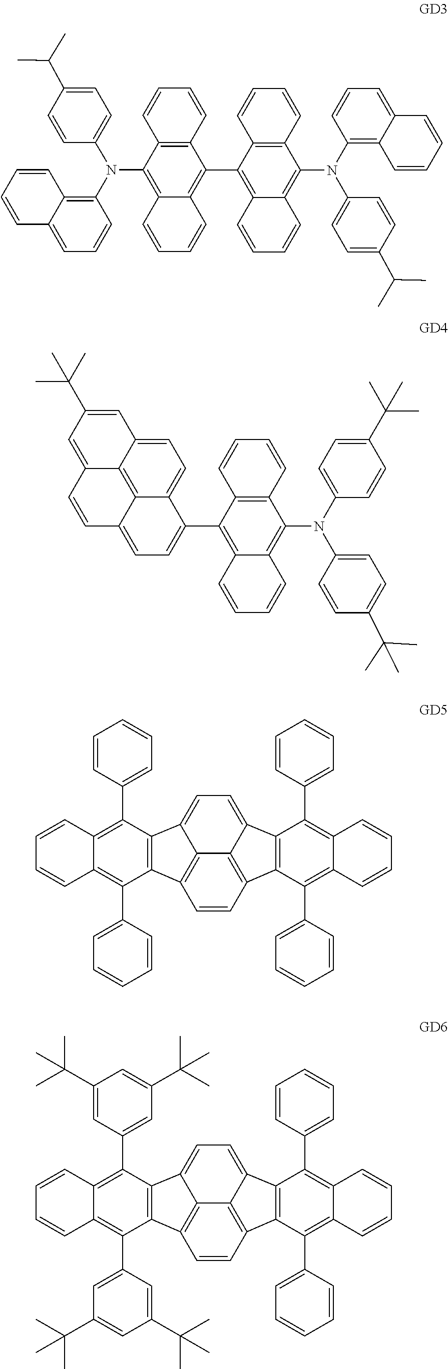

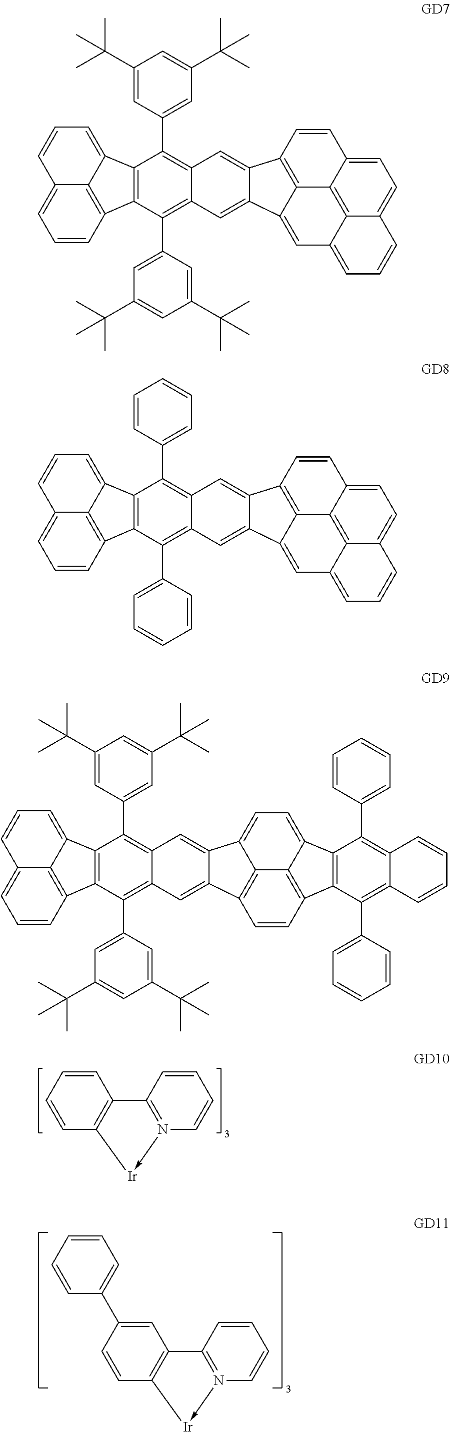

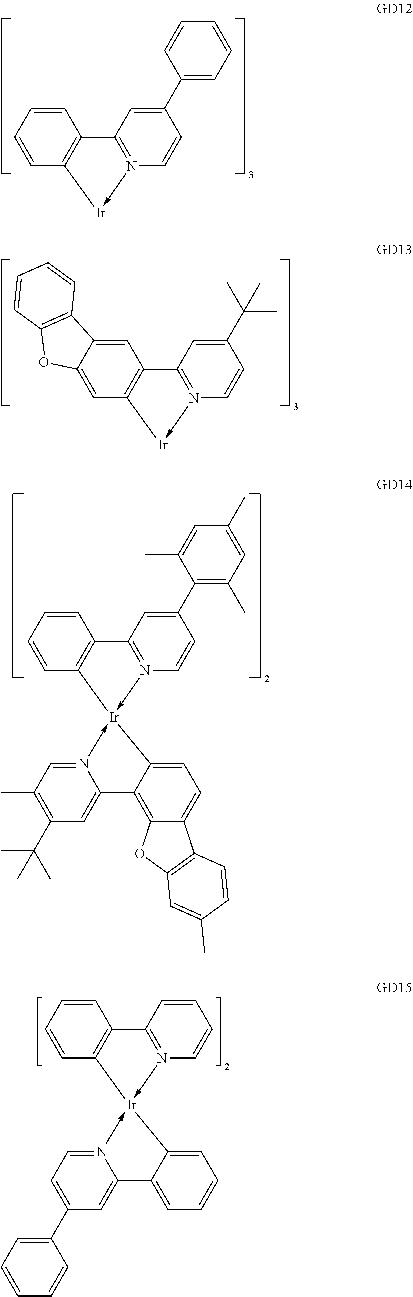

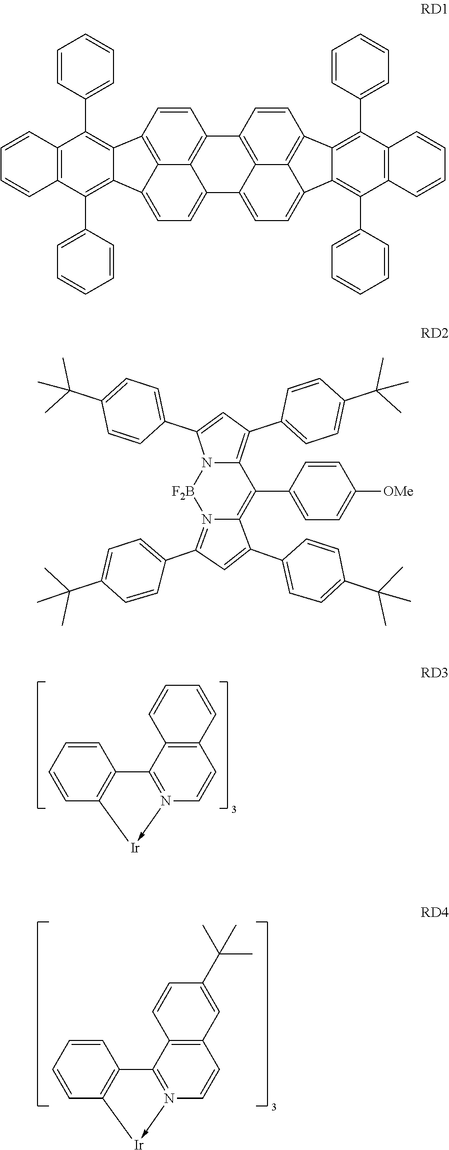

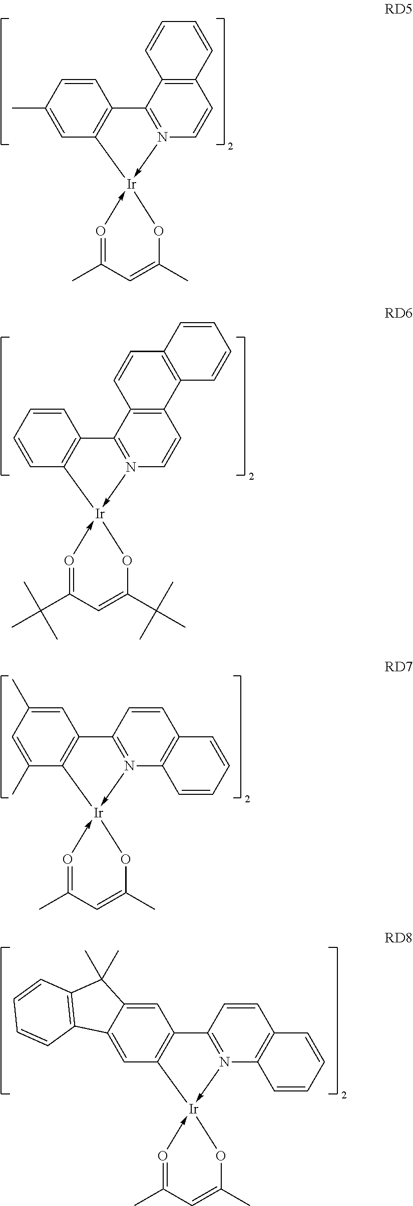

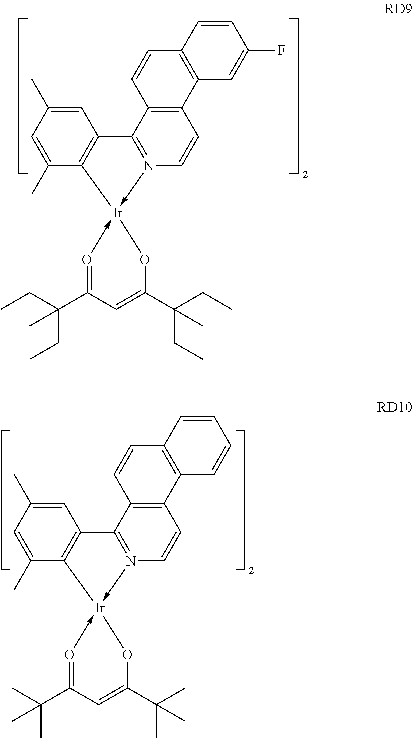

When the light-emitting material is a hydrocarbon compound, the material can reduce a decrease in luminous efficiency due to exciplex formation and a decrease in color purity due to a change in the emission spectrum of the light-emitting material caused by exciplex formation.

The hydrocarbon compound is a compound consisting only of carbon and hydrogen. Among the above exemplified compounds, BD7, BD8, GD5 to GD9, and RD1 are hydrocarbon compounds.

When the light-emitting material is a fused polycyclic compound containing a five-membered ring, the material has a high ionization potential and high resistance to oxidation. This can provide a highly durable device with a long lifetime. Among the above exemplified compounds, BD7, BD8, GD5 to GD9, and RD1 are such compounds.

Examples of a light-emitting layer host or an assist material contained in the light-emitting layer include aromatic hydrocarbon compounds and derivatives thereof, carbazole derivatives, dibenzofuran derivatives, dibenzothiophene derivatives, organoaluminum complexes, such as tris(8-quinolinolato)aluminum, organoberyllium complexes, and organoplatinum complexes

Non-limiting specific examples of a compound used as a light-emitting-layer host or an assist material contained in the light-emitting layer will be illustrated below.

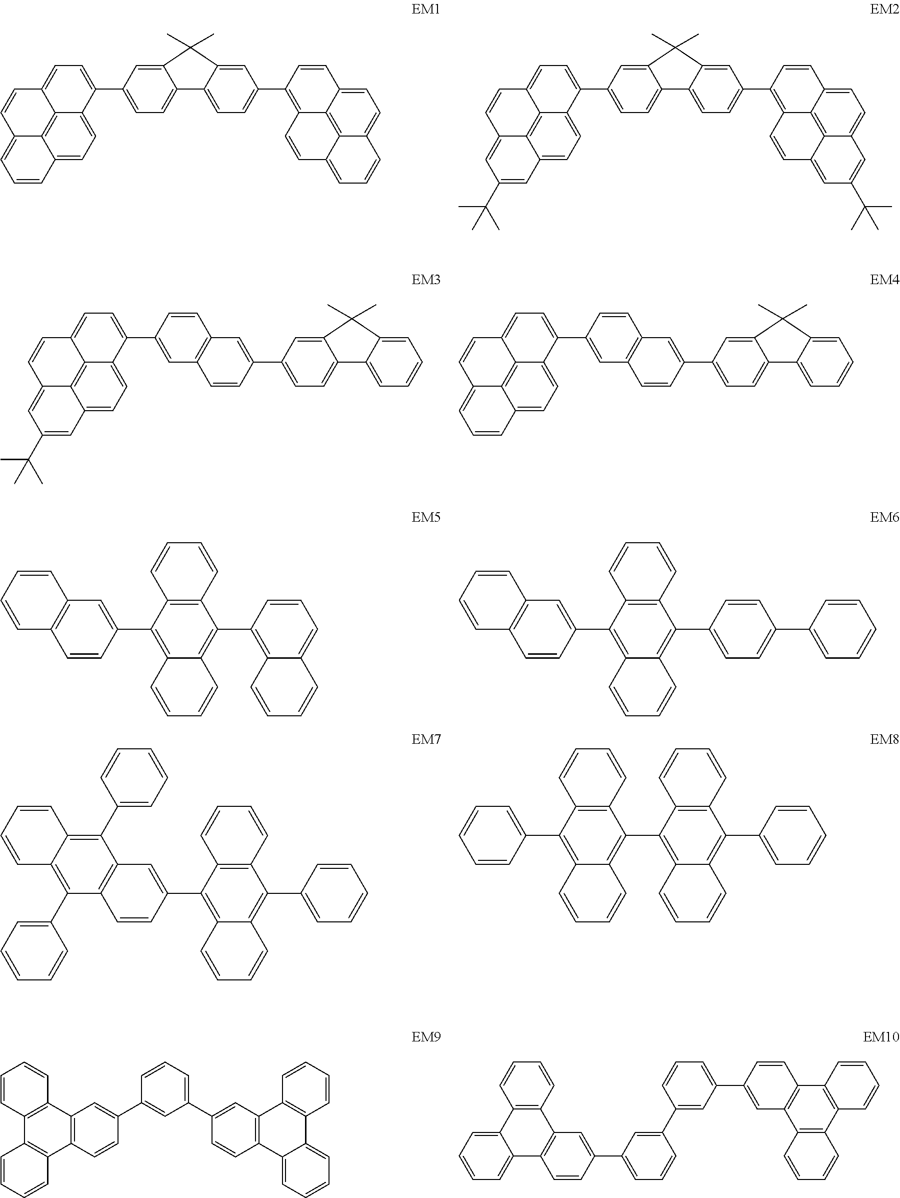

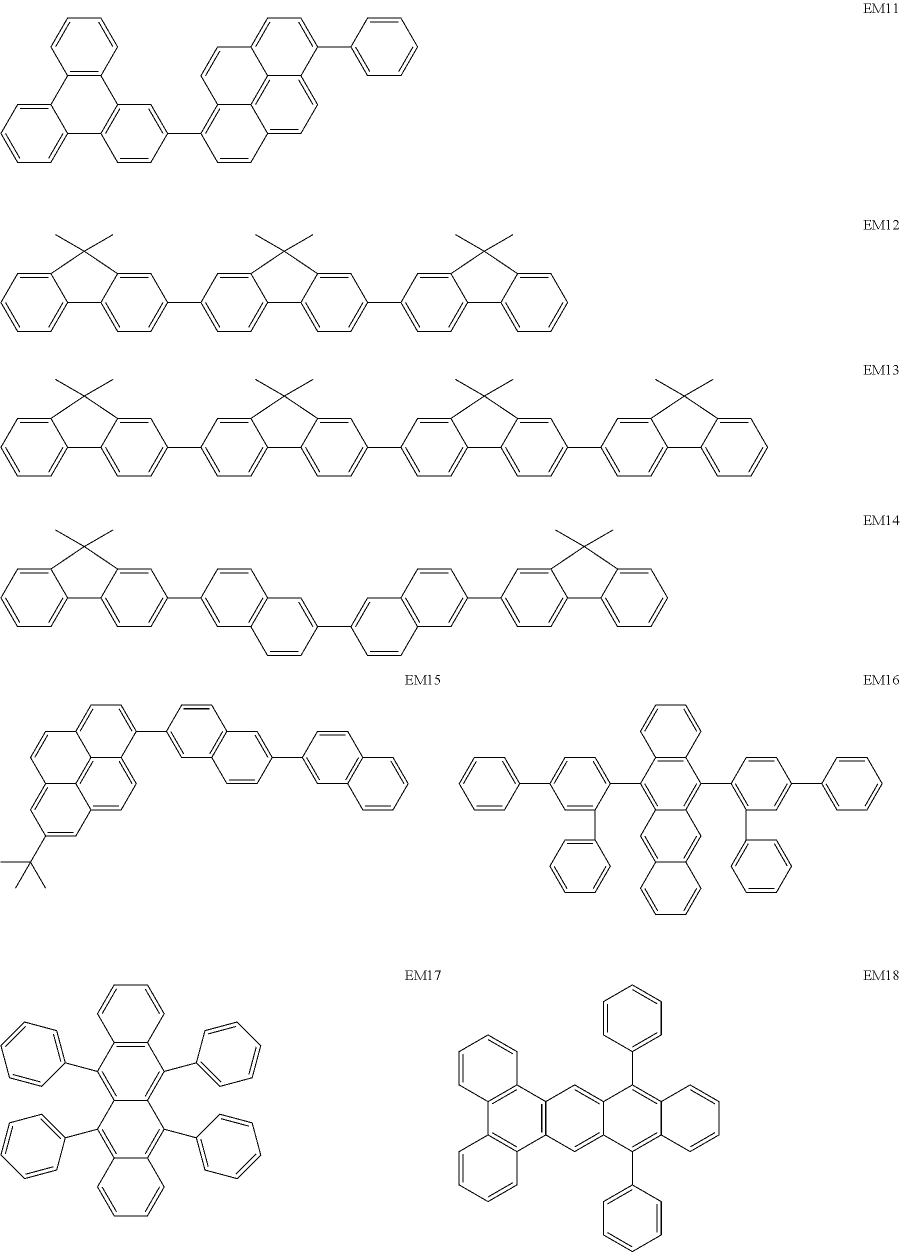

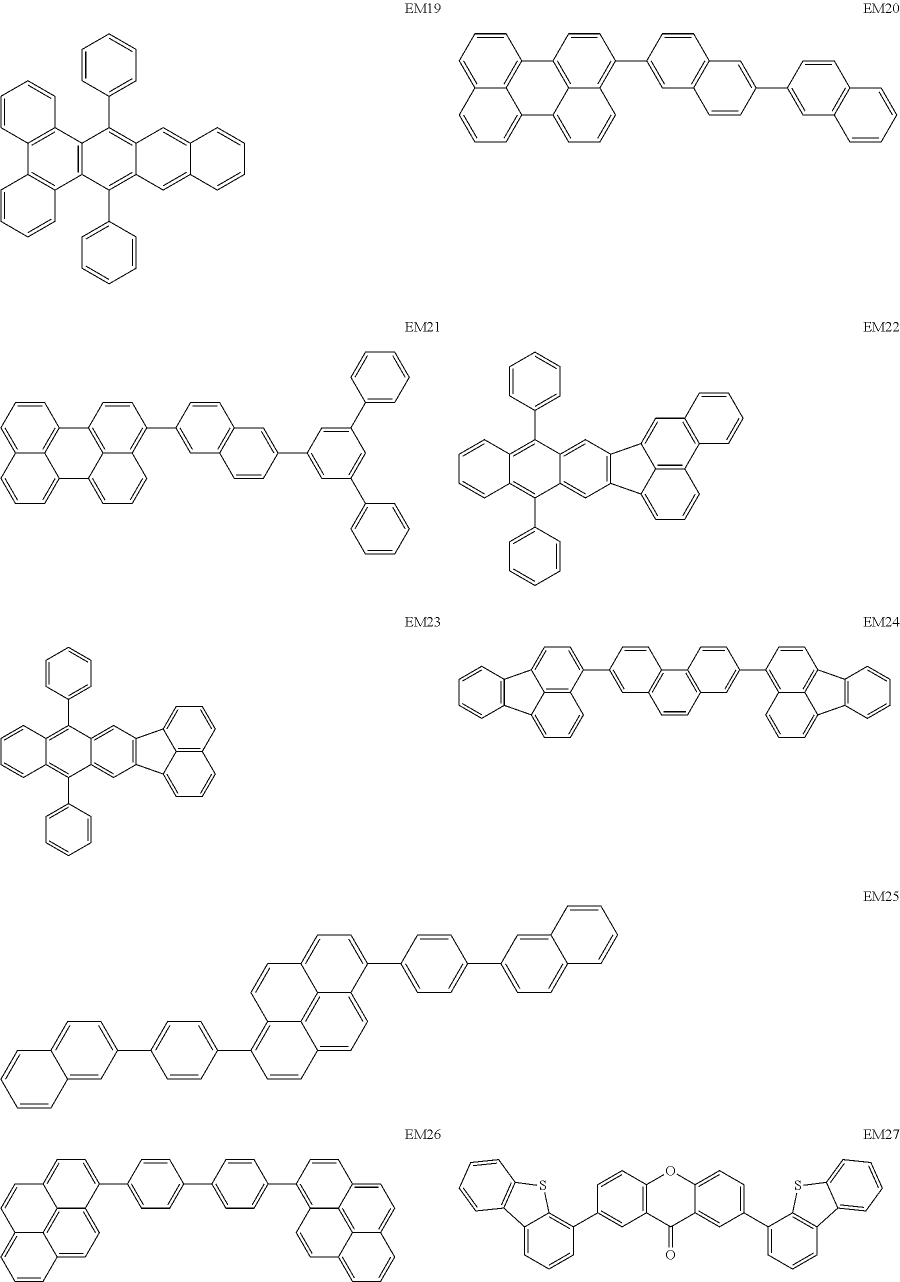

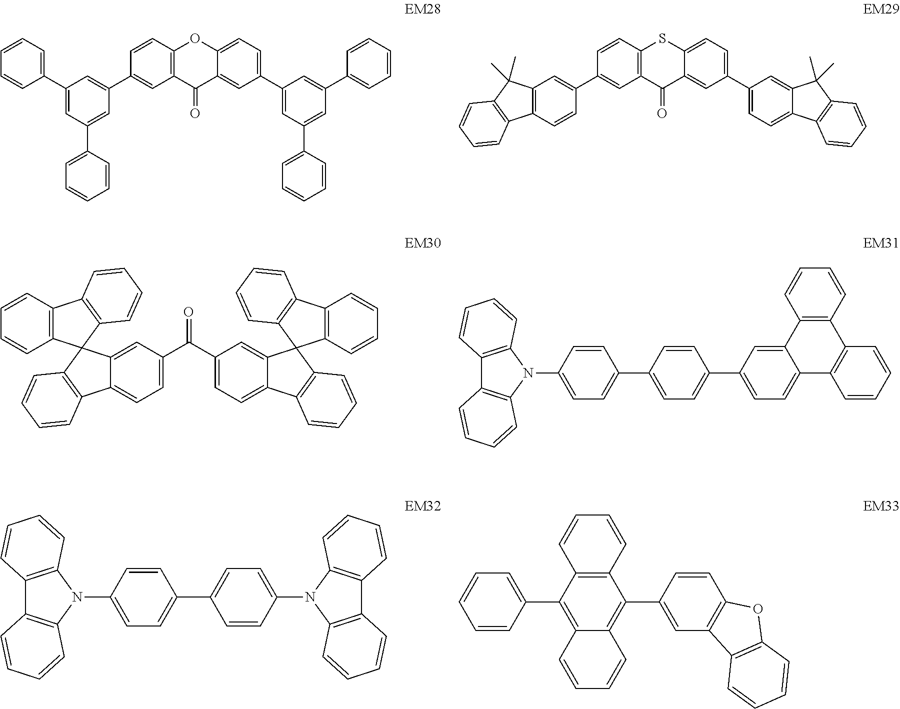 [SMILES: O=c1c2cc(-c3cc(-c4ccccc4)cc(-c4ccccc4)c3)ccc2oc2ccc(-c3cc(-c4ccccc4)cc(-c4ccccc4)c3)cc12 ; CC1(C)c2ccccc2-c2ccc(-c3ccc4sc5ccc(-c6ccc7c(c6)C(C)(C)c6ccccc6-7)cc5c(=O)c4c3)cc21 ; O=C(c1ccc2c(c1)C1(c3ccccc3-c3ccccc31)c1ccccc1-2)c1ccc2c(c1)C1(c3ccccc3-c3ccccc31)c1ccccc1-2 ; c1ccc2c(c1)c1ccccc1c1cc(-c3ccc(-c4ccc(-n5c6ccccc6c6ccccc65)cc4)cc3)ccc21 ; c1ccc2c(c1)c1ccccc1n2-c1ccc(-c2ccc(-n3c4ccccc4c4ccccc43)cc2)cc1 ; c1ccc(-c2c3ccccc3c(-c3ccc4oc5ccccc5c4c3)c3ccccc23)cc1]

When the host material is a hydrocarbon compound, the compound according to an embodiment of the present disclosure can easily trap electrons and holes to greatly contribute to higher efficiency. The hydrocarbon compound is a compound consisting only of carbon and hydrogen. Among the above exemplified compounds, EM1 to EM12 and EM16 to EM27 are hydrocarbon compounds.

The electron transport material can be freely-selected from materials capable of transporting electrons injected from the cathode to the light-emitting layer and is selected in consideration of, for example, the balance with the hole mobility of the hole transport material. Examples of a material having the ability to transport electrons include oxadiazole derivatives, oxazole derivatives, pyrazine derivatives, triazole derivatives, triazine derivatives, quinoline derivatives, quinoxaline derivatives, phenanthroline derivatives, organoaluminum complexes, and fused-ring compounds, such as fluorene derivatives, naphthalene derivatives, chrysene derivatives, and anthracene derivatives. The electron transport materials can be used for the hole-blocking layer.

Non-limiting specific examples of a compound used as the electron transport material will be illustrated below.

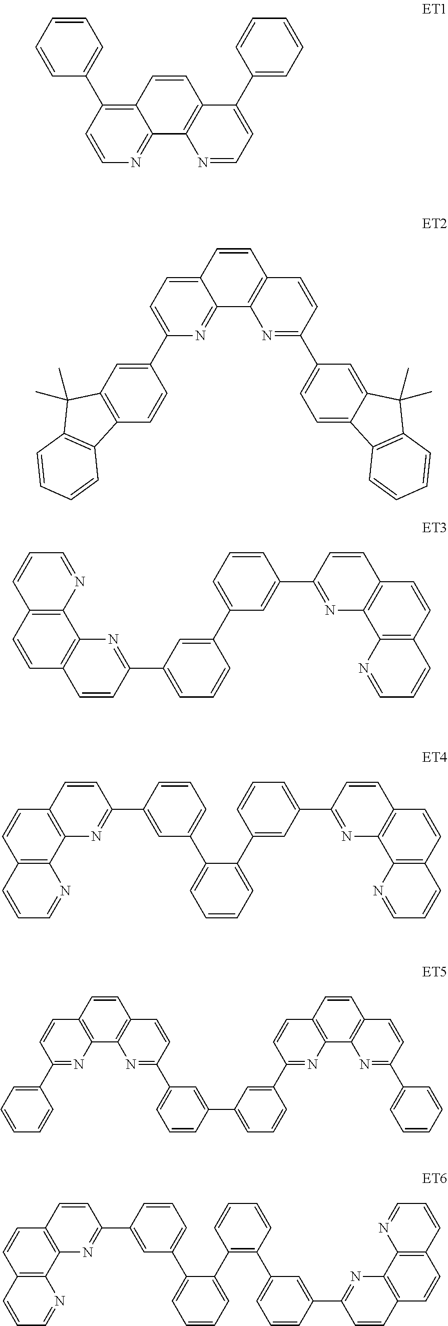

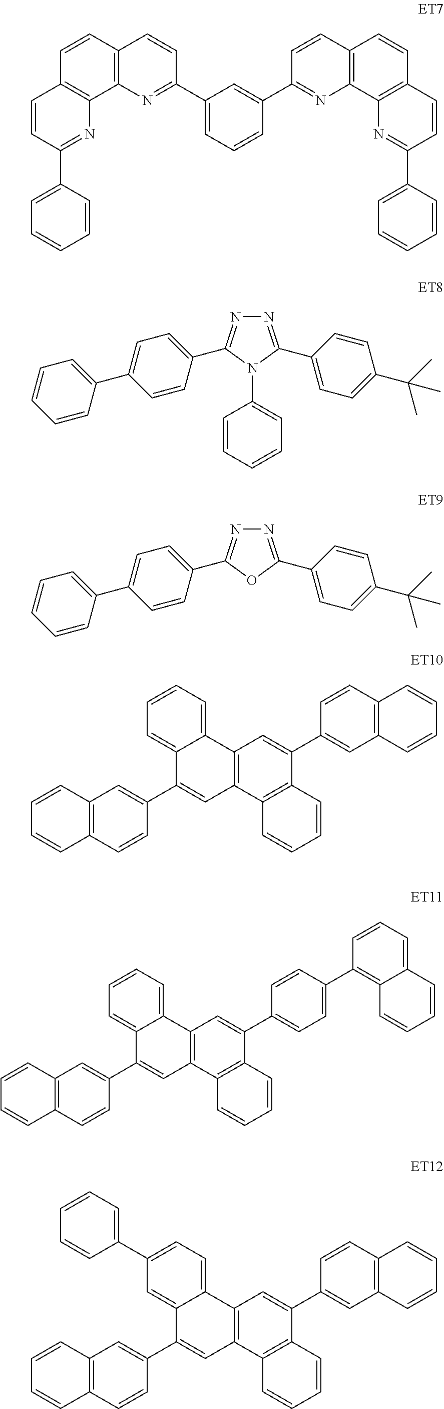

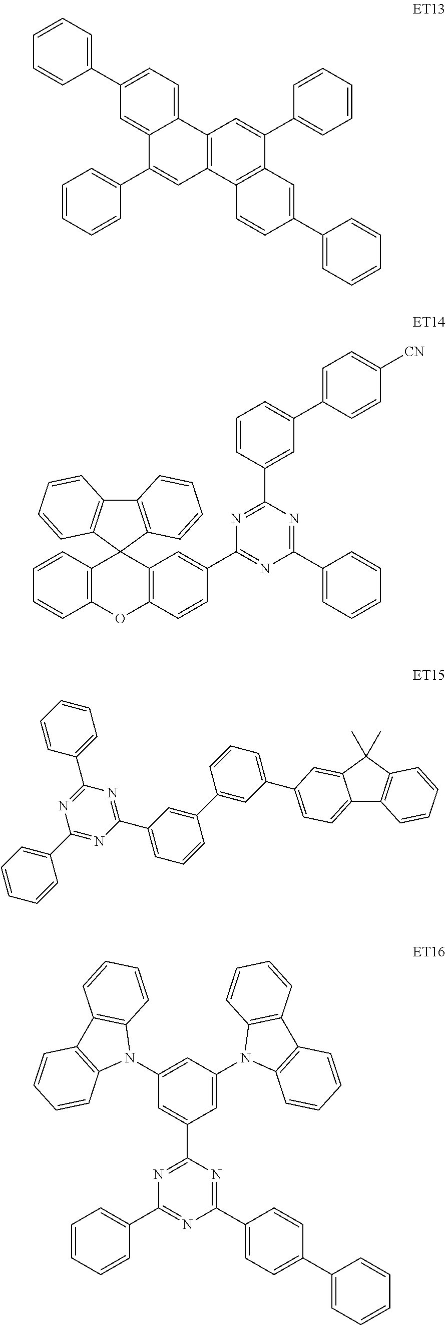

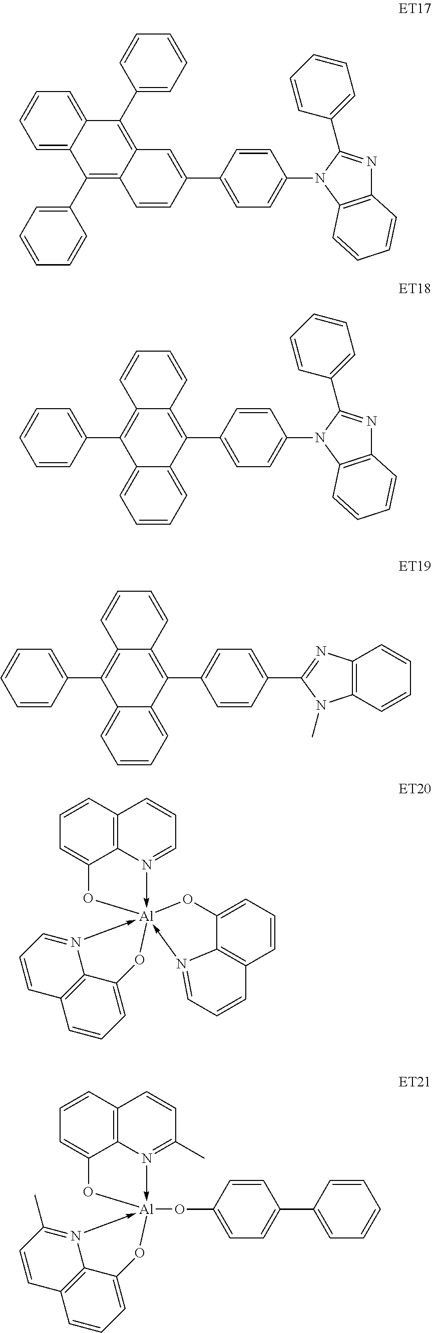

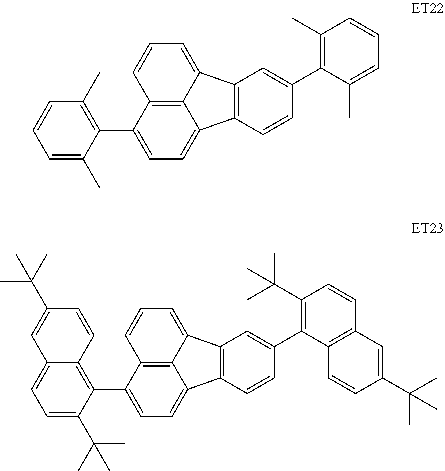

An electron injection material can be freely-selected from materials capable of easily injecting electrons from the cathode and is selected in consideration of, for example, the balance with the hole injection properties. As the organic compound, n-type dopants and reducing dopants are also included. Examples thereof include alkali metal-containing compounds such as lithium fluoride, lithium complexes such as lithium quinolinolate, benzimidazolidene derivatives, imidazolidene derivatives, fulvalene derivatives, and acridine derivatives.

These can also be used in combination with the above-mentioned electron transport material.

### Ink Composition

An ink composition according to the present embodiment will be described below.

The ink composition according to the present embodiment contains at least one compound represented by formula (2).

The compound represented by formula (2) has good solubility in an organic solvent and thus can be used in an ink composition. In the case of using the ink composition according to the present embodiment, a layer, particularly a light-emitting layer, composed of an organic compound constituting the organic light-emitting device according to the present embodiment can be produced by a coating method, thereby easily producing a relatively inexpensive device having a large area. Examples of a solvent that dissolves the compound represented by formula (2) include toluene, xylene, mesitylene, dioxane, methylnaphthalene, tetrahydrofuran, diglyme, 1,2-dichlorobenzene, and 1,2-dichloropropane. These solvents can be used alone or in combination of two or more. Among these, a solvent having an appropriate evaporation rate, specifically, a solvent having a boiling point of about 70° C. to about 200° C. can be used because a thin film having a uniform thickness is easily formed. The ink composition according to the present embodiment may further contain a compound serving as an additive. Examples of the compound serving as an additive include the above-mentioned known light-emitting-layer hosts, light emission-assisting materials, hole transport materials, light-emitting materials, and electron transport materials.

The concentration of the compound represented by formula (2) in the ink composition according to the present embodiment is preferably 0.05% or more by weight and 20% or less by weight, more preferably 0.1% or more by weight and 5% or less by weight, based on the total of the composition.

The ink composition according to the present embodiment can be formed into a film by, for example, a spin coating method, a bar coating method, a slit coating method, an ink jet method, a nozzle coating method, a casting method, or a gravure printing method. A display apparatus, such as a display, can be produced by forming the organic light-emitting devices according to an embodiment of the present disclosure over electrodes formed in a pixel pattern.

### Configuration of Organic Light-Emitting Device

The organic light-emitting device includes, over a substrate, an insulating layer, a first electrode, an organic compound layer, and a second electrode. A protective layer, a color filter, a microlens may be disposed over the second electrode. In the case of disposing the color filter, a planarization layer may be disposed between the protective layer and the color filter. The planarization layer can be composed of, for example, an acrylic resin. The same applies when a planarization layer is provided between the color filter and the microlens. One of the first electrode and the second electrode may be an anode, and the other may be a cathode.

### Substrate

Examples of the substrate include silicon wafers, quartz substrates, glass substrates, resin substrates, and metal substrates. The substrate may include a switching element, such as a transistor, a line, and an insulating layer thereon. Any material can be used for the insulating layer as long as a contact hole can be formed in such a manner that a line can be coupled to the first electrode and as long as insulation with a non-connected line can be ensured. For example, a resin, such as polyimide, silicon oxide, or silicon nitride, can be used.

### Electrode

A pair of electrodes can be used. The pair of electrodes may be an anode and a cathode.

In the case where an electric field is applied in the direction in which the organic light-emitting device emits light, an electrode having a higher potential is the anode, and the other is the cathode. It can also be said that the electrode that supplies holes to the light-emitting layer is the anode and that the electrode that supplies electrons is the cathode.

As the component material of the anode, a material having a work function as high as possible can be used. Examples of the material that can be used include elemental metals, such as gold, platinum, silver, copper, nickel, palladium, cobalt, selenium, vanadium, and tungsten, mixtures thereof, alloys of combinations thereof, and metal oxides, such as tin oxide, zinc oxide, indium oxide, indium-tin oxide (ITO), and indium-zinc oxide. Additionally, conductive polymers, such as polyaniline, polypyrrole, and polythiophene, can be used.

These electrode materials may be used alone or in combination of two or more. The anode may be formed of a single layer or multiple layers.

When the anode is used as a reflective electrode, for example, chromium, aluminum, silver, titanium, tungsten, molybdenum, an alloy thereof, or a stack thereof can be used. These materials can also be used to act as a reflective film that does not have the role of an electrode. When the anode is used as a transparent electrode, a transparent conductive oxide layer composed of, for example, indium-tin oxide (ITO) or indium-zinc oxide may be used; however, the anode is not limited thereto.

The electrode can be formed by photolithography.

As the component material of the cathode, a material having a lower work function can be used. Examples thereof include elemental metals such as alkali metals, e.g., lithium, alkaline-earth metals, e.g., calcium, aluminum, titanium, manganese, silver, lead, and chromium, and mixtures thereof. Alloys of combinations of these elemental metals can also be used. For example, magnesium-silver, aluminum-lithium, aluminum-magnesium, silver-copper, and zinc-silver can be used. Metal oxides, such as indium-tin oxide (ITO), can also be used. These electrode materials may be used alone or in combination of two or more. The cathode may have a single-layer structure or a multilayer structure. In particular, silver can be used. To reduce the aggregation of silver, a silver alloy can be used. Any alloy ratio may be used as long as the aggregation of silver can be reduced. The ratio of silver to another metal may be, for example, 1:1 or 3:1.

A top emission device may be provided using the cathode formed of a conductive oxide layer composed of, for example, ITO. A bottom emission device may be provided using the cathode formed of a reflective electrode composed of, for example, aluminum (Al). Any type of cathode may be used. Any method for forming the cathode may be employed. For example, a direct-current or alternating-current sputtering technique can be employed because good film coverage is obtained and thus the resistance is easily reduced.

### Organic Compound Layer

The organic compound layer may be formed of a single layer or multiple layers. When multiple layers are present, they may be referred to as a hole injection layer, a hole transport layer, an electron-blocking layer, a light-emitting layer, a hole-blocking layer, an electron transport layer, or an electron injection layer in accordance with their functions. The organic compound layer is mainly composed of an organic compound, and may contain inorganic atoms and an inorganic compound. For example, the organic compound layer may contain, for example, copper, lithium, magnesium, aluminum, iridium, platinum, molybdenum, or zinc. The organic compound layer may be disposed between the first electrode and the second electrode, and may be disposed in contact with the first electrode and the second electrode.

### Protective Layer

A protective layer may be disposed on the cathode. For example, a glass member provided with a moisture absorbent can be bonded to the cathode to reduce the entry of, for example, water into the organic compound layer, thereby reducing the occurrence of display defects. In another embodiment, a passivation film composed of, for example, silicon nitride may be disposed on the cathode to reduce the entry of, for example, water into the organic compound layer. For example, after the formation of the cathode, the substrate may be transported to another chamber without breaking the vacuum, and a silicon nitride film having a thickness of 2 μm may be formed by a chemical vapor deposition (CVD) method to provide a protective layer. After the film deposition by the CVD method, a protective layer may be formed by an atomic layer deposition (ALD) method. Non-limiting examples of the material of the layer formed by the ALD method may include silicon nitride, silicon oxide, and aluminum oxide. Silicon nitride may be deposited by the CVD method on the layer formed by the ALD method. The film formed by the ALD method may have a smaller thickness than the film formed by the CVD method. Specifically, the film thickness may be 50% or less, even 10% or less.

### Color Filter

A color filter may be disposed on the protective layer. For example, a color filter may be disposed on another substrate in consideration of the size of the organic light-emitting device and bonded to the substrate provided with the organic light-emitting device. A color filter may be formed by patterning on the protective layer using photolithography. The color filter may be composed of a polymer.

### Planarization Layer

A planarization layer may be disposed between the color filter and the protective layer. The planarization layer is provided for the purpose of reducing the unevenness of the layer underneath. The planarization layer may be referred to as a “material resin layer” without limiting its purpose. The planarization layer may be composed of an organic compound. A low- or high-molecular-weight organic compound may be used. A high-molecular-weight organic compound can be used.

The planarization layers may be disposed above and below (or on) the color filter and may be composed of the same or different component materials. Specific examples thereof include poly(vinyl carbazole) resins, polycarbonate resins, polyester resins, acrylonitrile butadiene styrene (ABS) resins, acrylic resins, polyimide resins, phenolic resins, epoxy resins, silicone resins, and urea resins.

### Microlens

An organic light-emitting apparatus may include an optical member, such as a microlens, on the outgoing light side. The microlens can be composed of, for example, an acrylic resin or an epoxy resin. The microlens may be used to increase the amount of light emitted from the organic light-emitting apparatus and to control the direction of the light emitted. The microlens may have a hemispherical shape. In the case of a hemispherical shape, among tangents to the hemisphere, there is a tangent parallel to the insulating layer. The point of contact of the tangent with the hemisphere is the vertex of the microlens. The vertex of the microlens can be determined in the same way for any cross-sectional view. That is, among the tangents to the semicircle of the microlens in the cross-sectional view, there is a tangent parallel to the insulating layer, and the point of contact of the tangent with the semicircle is the vertex of the microlens.

The midpoint of the microlens can be defined. In the cross section of the microlens, when a segment is hypothetically drawn from the point where an arc shape ends to the point where another arc shape ends, the midpoint of the segment can be referred to as the midpoint of the microlens. The cross section to determine the vertex and midpoint may be a cross section perpendicular to the insulating layer.

### Opposite Substrate

An opposite substrate may be disposed on the planarization layer. The opposite substrate is disposed at a position corresponding to the substrate described above and thus is called an opposite substrate. The opposite substrate may be composed of the same material as the substrate described above. When the above-described substrate is referred to as a first substrate, the opposite substrate may be referred to as a second substrate.

### Formation of Organic Compound Layer

The organic compound layer, such as the hole injection layer, the hole transport layer, the electron-blocking layer, the light-emitting layer, the hole-blocking layer, the electron transport layer, or the electron injection layer, included in the organic light-emitting device according to an embodiment of the present disclosure is formed by a method described below.

For the organic compound layer included in the organic light-emitting device according to an embodiment of the present disclosure, a dry process, such as a vacuum evaporation method, an ionized evaporation method, sputtering, or plasma, may be employed. Alternatively, instead of the dry process, it is also possible to employ a wet process in which a material is dissolved in an appropriate solvent and then a film is formed by a known coating method, such as spin coating, dipping, a casting method, a Langmuir-Blodgett (LB) technique, or an ink jet method.

When the layer is formed by, for example, the vacuum evaporation method or the solution coating method, crystallization and so forth are less likely to occur, and good stability with time is obtained. In the case of forming a film by the coating method, the film may be formed in combination with an appropriate binder resin.

Non-limiting examples of the binder resin include poly(vinyl carbazole) resins, polycarbonate resins, polyester resins, acrylonitrile butadiene styrene (ABS) resins, acrylic resins, polyimide resins, phenolic resins, epoxy resins, silicone resins, and urea resins.

These binder resins may be used alone as a homopolymer or copolymer or in combination as a mixture of two or more. Furthermore, additives, such as a known plasticizer, antioxidant, and ultraviolet absorber, may be used, as needed.

### Formation of Light-Emitting Layer

In the organic light-emitting device according to an embodiment of the present disclosure, the light-emitting layer is formed by a coating method because the compound represented by formula (1) has high solubility in an organic solvent. Examples of the coating method include a spin coating method, a slit coater method, a printing method, an ink jet method, a dispensing method, and a spray method.

### Pixel Circuit

An light-emitting apparatus including organic light-emitting devices may include pixel circuits coupled to the organic light-emitting devices. Each of the pixel circuits may be of an active matrix type, which independently controls the emission of first and second light-emitting devices. The active matrix type circuit may be voltage programming or current programming. A driving circuit includes the pixel circuit for each pixel. The pixel circuit may include a light-emitting device, a transistor to control the luminance of the light-emitting device, a transistor to control the timing of the light emission, a capacitor to retain the gate voltage of the transistor to control the luminance, and a transistor to connect to GND without using the light-emitting device.

The light-emitting apparatus includes a display area and a peripheral area disposed around the display area. The display area includes a pixel circuit, and the peripheral area includes a display control circuit. The mobility of a transistor contained in the pixel circuit may be lower than the mobility of a transistor contained in the display control circuit.

The gradient of the current-voltage characteristics of the transistor contained in the pixel circuit may be smaller than the gradient of the current-voltage characteristic of the transistor contained in the display control circuit. The gradient of the current-voltage characteristics can be measured by what is called Vg-Ig characteristics.

The transistor contained in the pixel circuit is a transistor coupled to a light-emitting device, such as a first light-emitting device.

### Pixel

The organic light-emitting apparatus includes multiple pixels. Each pixel includes subpixels configured to emit colors different from each other. The subpixels may have respective red, green, and blue (RGB) emission colors.

Light emerges from a region of the pixel, also called a pixel aperture. This region is the same as a first region.

The pixel aperture may be 15 μm or less, and may be 5 μm or more. More specifically, the pixel aperture may be, for example, 11 μm, 9.5 μm, 7.4 μm, or 6.4 μm.

The distance between subpixels may be 10 μm. Specifically, the distance may be 8 μm, 7.4 μm, or 6.4 μm.

The pixels may be arranged in a known pattern in plan view. For example, a stripe pattern, a delta pattern, a Pen Tile matrix pattern, or the Bayer pattern may be used. The shape of each subpixel in plan view may be any known shape. Examples of the shape of the subpixel include quadrilaterals, such as rectangles and rhombi, and hexagons. Of course, if the shape is close to a rectangle, rather than an exact shape, it is included in the rectangle. The shape of the subpixel and the pixel arrangement can be used in combination.

### Application of Organic Light-Emitting Device According to One Embodiment of the Present Disclosure

The organic light-emitting device according to an embodiment of the present disclosure can be used as a component member of a display apparatus or lighting apparatus. Other applications include exposure light sources for electrophotographic image-forming apparatuses, backlights for liquid crystal display apparatuses, and light-emitting apparatuses including white-light sources and color filters.

The display apparatus may be an image information-processing unit including an image input unit configured to receive image information from an area or linear CCD sensor, a memory card, or any other source, an information-processing unit configured to process the input information, and a display unit configured to display the input image.

The display unit of an image pickup apparatus or an inkjet printer may have a touch panel function. The driving mode of the touch panel function may be, but is not particularly limited to, an infrared mode, an electrostatic capacitance mode, a resistive film mode, or an electromagnetic inductive mode. The display apparatus may also be used for a display unit of a multifunction printer.

The following describes a display apparatus according to the present embodiment with reference to the attached drawings.

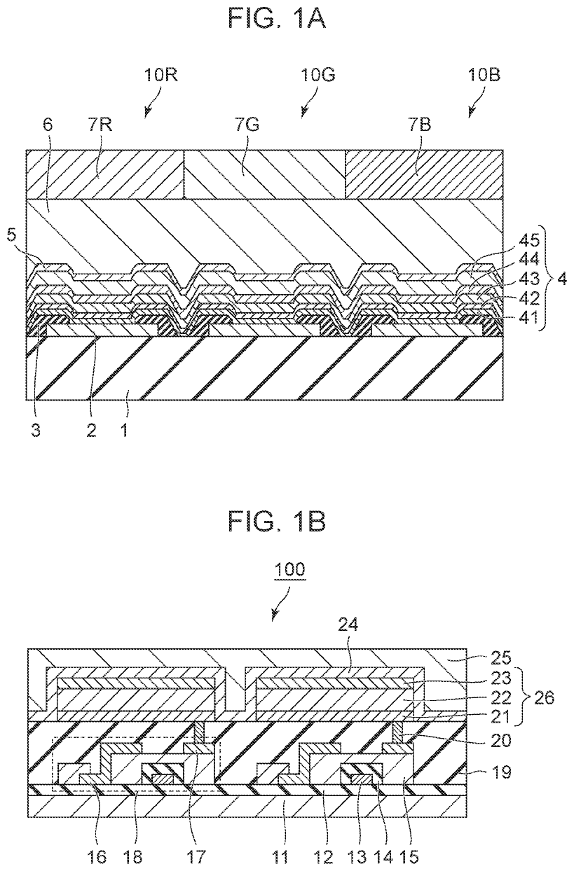

FIGS. 1A and 1B are each a schematic cross-sectional view of an example of a display apparatus including organic light-emitting devices and transistors coupled to the respective organic light-emitting devices. Each of the transistors is an example of an active element. The transistors may be thin-film transistors (TFTs).

FIG. 1A is an example of pixels that are components of the display apparatus according to the present embodiment. Each of the pixels includes subpixels 10. The subpixels are divided into 10R, 10G, and 10B according to their light emission. The emission colors may be distinguished by the wavelength of light emitted from the light-emitting layer. Light emitted from the subpixels may be selectively transmitted or color-converted with, for example, a color filter. Each subpixels includes a reflective electrode 2 serving as a first electrode, an insulating layer 3 covering the edge of the reflective electrode 2, an organic compound layer 4 covering the first electrode and the insulating layer, a transparent electrode 5, a protective layer 6, and a color filter 7, over an interlayer insulating layer 1.

The transistors and capacitive elements may be disposed under or in the interlayer insulating layer 1.

Each transistor may be electrically coupled to a corresponding one of the first electrodes through a contact hole (not illustrated).

The insulating layer 3 is also called a bank or pixel separation film. The insulating layer covers the edge of each first electrode and surrounds the first electrode. Portions that are not covered with the insulating layer are in contact with the organic compound layer 4 and serve as light-emitting regions.

The organic compound layer 4 includes a hole injection layer 41, a hole transport layer 42, a first light-emitting layer 43, a second light-emitting layer 44, and an electron transport layer 45.

The second electrode 5 may be a transparent electrode, a reflective electrode, or a semi-transparent electrode.

The protective layer 6 reduces the penetration of moisture into the organic compound layer. Although the protective layer is illustrated as a single layer, the protective layer may include multiple layers, and each layer may be an inorganic compound layer or an organic compound layer.

The color filter 7 is separated into 7R, 7G, and 7B according to its color. The color filter may be disposed on a planarizing film (not illustrated). A resin protective layer (not illustrated) may be disposed on the color filter. The color filter may be disposed on the protective layer 6. Alternatively, the color filter may be disposed on an opposite substrate, such as a glass substrate, and then bonded.

A display apparatus 100 illustrated in FIG. 1B includes organic light-emitting devices 26 and TFTs 18 as an example of transistors. A substrate 11 composed of a material, such as glass or silicon, is provided, and an insulating layer 12 is disposed thereon. Active elements 18, such as the TFTs, are disposed on the insulating layer. The gate electrode 13, the gate insulating film 14, and the semiconductor layer 15 of each of the active elements are disposed thereon. Each TFT 18 further includes a semiconductor layer 15, a drain electrode 16, and a source electrode 17. The TFTs 18 are overlaid with an insulating film 19. Anode 21 included in the organic light-emitting devices 26 is coupled to the source electrodes 17 through contact holes 20 provided in the insulating film.

The mode of electrical connection between the electrodes (anode and cathode) included in each organic light-emitting device 26 and the electrodes (source electrode and drain electrode) included in a corresponding one of the TFTs is not limited to the mode illustrated in FIG. 1B. That is, it is sufficient that any one of the anode and the cathode is electrically coupled to any one of the source electrode and the drain electrode of the TFT. The term “TFT” refers to a thin-film transistor.

In the display apparatus 100 illustrated in FIG. 1B, although each organic compound layer 22 is illustrated as a single layer, the organic compound layer 22 may include multiple layers. To reduce the deterioration of the organic light-emitting devices, a first protective layer 24 and a second protective layer 25 are disposed on the cathodes 23.

In the display apparatus 100 illustrated in FIG. 1B, although the transistors are used as switching elements, other switching elements may be used instead.

The transistors used in the display apparatus 100 illustrated in FIG. 1B are not limited to transistors using a single-crystal silicon wafer, but may also be thin-film transistors including active layers on the insulating surface of a substrate. Examples of the material of the active layers include single-crystal silicon, non-single-crystal silicon, such as amorphous silicon and microcrystalline silicon; and non-single-crystal oxide semiconductors, such as indium zinc oxide and indium gallium zinc oxide. Thin-film transistors are also called TFT elements.

The transistors in the display apparatus 100 illustrated in FIG. 1B may be formed in the substrate, such as a Si substrate. The expression “formed in the substrate” indicates that the transistors are produced by processing the substrate, such as a Si substrate. In the case where the transistors are formed in the substrate, the substrate and the transistors can be deemed to be integrally formed.

In the organic light-emitting device according to the present embodiment, the luminance is controlled by the TFT devices, which are an example of switching elements; thus, an image can be displayed at respective luminance levels by arranging multiple organic light-emitting devices in the plane. The switching devices according to the present embodiment are not limited to the TFT devices and may be low-temperature polysilicon transistors or active-matrix drivers formed on a substrate such as a Si substrate. The expression “on a substrate” can also be said to be “in the substrate”. Whether transistors are formed in the substrate or TFT devices are used is selected in accordance with the size of a display unit. For example, in the case where the display unit has a size of about 0.5 inches, organic light-emitting devices can be disposed on a Si substrate.

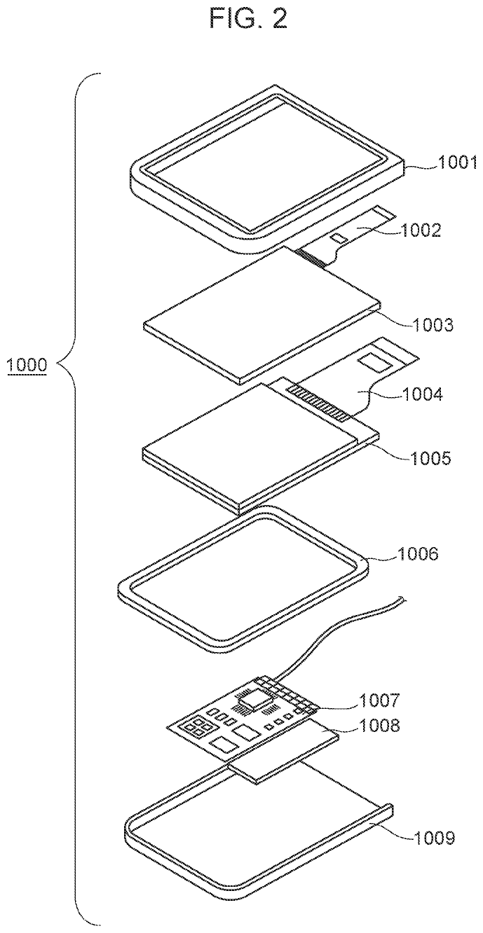

FIG. 2 is a schematic view illustrating an example of a display apparatus according to the present embodiment. A display apparatus 1000 may include a touch panel 1003, a display panel 1005, a frame 1006, a circuit substrate 1007, and a battery 1008, disposed between an upper cover 1001 and a lower cover 1009. The touch panel 1003 and the display panel 1005 are coupled to flexible printed circuits FPCs 1002 and 1004, respectively. The circuit substrate 1007 includes printed transistors. The battery 1008 need not be provided unless the display apparatus is a portable apparatus. The battery 1008 may be disposed at a different position even if the display apparatus is a portable apparatus.

The display apparatus according to the present embodiment may include a color filter having red, green, and blue portions. In the color filter, the red, green, and blue portions may be arranged in a delta arrangement.

The display apparatus according to the present embodiment may be used for the display unit of a portable terminal. In that case, the display apparatus may have both a display function and an operation function. Examples of the portable terminal include mobile phones such as smartphones, tablets, and head-mounted displays.

The display apparatus according to the present embodiment may be used for a display unit of an image pickup apparatus including an optical unit including multiple lenses and an image pickup device that receives light passing through the optical unit. The image pickup apparatus may include a display unit that displays information acquired by the image pickup device. The display unit may be a display unit exposed to the outside of the image pickup apparatus or a display unit disposed in a finder. The image pickup apparatus may be a digital camera or a digital camcorder.

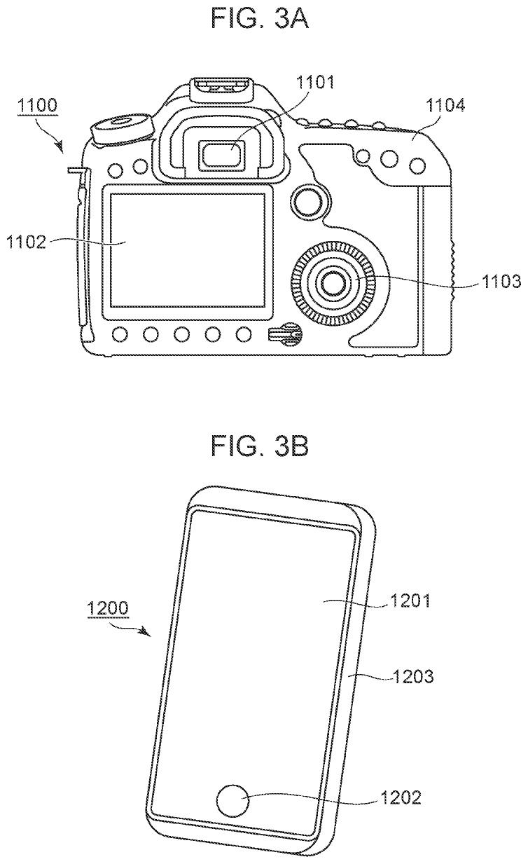

FIG. 3A is a schematic view illustrating an example of an image pickup apparatus according to the present embodiment. An image pickup apparatus 1100 may include a viewfinder 1101, a rear display 1102, an operation unit 1103, and a housing 1104. The viewfinder 1101 may include the display apparatus according to the present embodiment. In this case, the display apparatus may display environmental information, imaging instructions, and so forth in addition to an image to be captured. The environmental information may include, for example, the intensity of external light, the direction of external light, the moving speed of a subject, and the possibility that a subject is shielded by a shielding material.

The timing suitable for imaging is only for a short time. It is thus better to display the information as soon as possible. Accordingly, the display apparatus including the organic light-emitting device according to an embodiment of the present embodiment can be used. The display apparatus including the organic light-emitting device can be used more suitably than liquid crystal displays for such apparatuses required to have a high display speed.

The image pickup apparatus 1100 includes an optical unit (not illustrated). The optical unit includes multiple lenses and is configured to form an image on an image pickup device in the housing 1104. The relative positions of the multiple lenses can be adjusted to adjust the focal point. This operation can also be performed automatically. The image pickup apparatus may translate to a photoelectric conversion apparatus. Examples of an image capturing method employed in the photoelectric conversion apparatus may include a method for detecting a difference from the previous image and a method of cutting out an image from images always recorded, instead of sequentially capturing images.

FIG. 3B is a schematic view illustrating an example of an electronic apparatus according to the present embodiment. An electronic apparatus 1200 includes a display unit 1201, an operation unit 1202, and a housing 1203. The housing 1203 may accommodate a circuit, a printed circuit board including the circuit, a battery, and a communication unit. The operation unit 1202 may be a button or a touch-screen-type reactive unit. The operation unit may be a biometric recognition unit that recognizes a fingerprint to release the lock or the like. An electronic apparatus having a communication unit can also be referred to as a communication apparatus. The electronic apparatus may further have a camera function by being equipped with a lens and an image pickup device. An image captured by the camera function is displayed on the display unit. Examples of the electronic apparatus include smartphones and notebook computers.

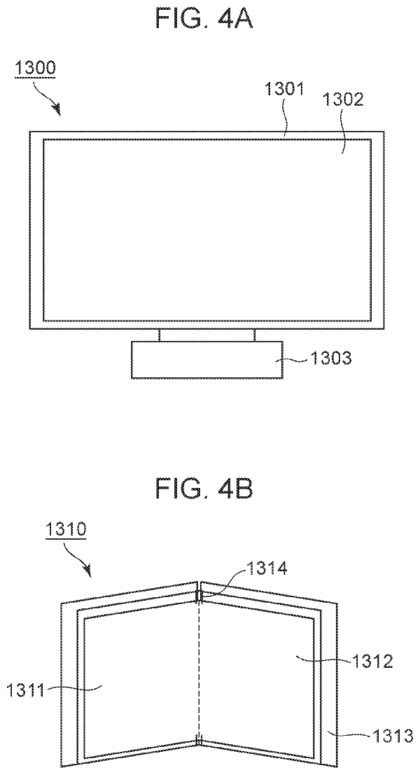

FIG. 4A is a schematic view illustrating an example of the display apparatus according to the present embodiment. FIG. 4A illustrates a display apparatus, such as a television monitor or a PC monitor. A display apparatus 1300 includes a frame 1301 and a display unit 1302. The light-emitting apparatus according to the present embodiment may be used for the display unit 1302.

The display apparatus 1300 includes a base 1303 that supports the frame 1301 and the display unit 1302. The base 1303 is not limited to the structure illustrated in FIG. 4A. The lower side of the frame 1301 may also serve as a base.

The frame 1301 and the display unit 1302 may be curved. These may have a radius of curvature of 5,000 mm or more and 6,000 mm or less.

FIG. 4B is a schematic view illustrating another example of a display apparatus according to the present embodiment. A display apparatus 1310 illustrated in FIG. 4B can be folded and is what is called a foldable display apparatus. The display apparatus 1310 includes a first display portion 1311, a second display portion 1312, a housing 1313, and an inflection point 1314. The first display portion 1311 and the second display portion 1312 may include the light-emitting apparatus according to the present embodiment. The first display portion 1311 and the second display portion 1312 may be a single, seamless display apparatus. The first display portion 1311 and the second display portion 1312 can be divided from each other at the inflection point. The first display portion 1311 and the second display portion 1312 may display different images. Alternatively, a single image may be displayed in the first and second display portions.

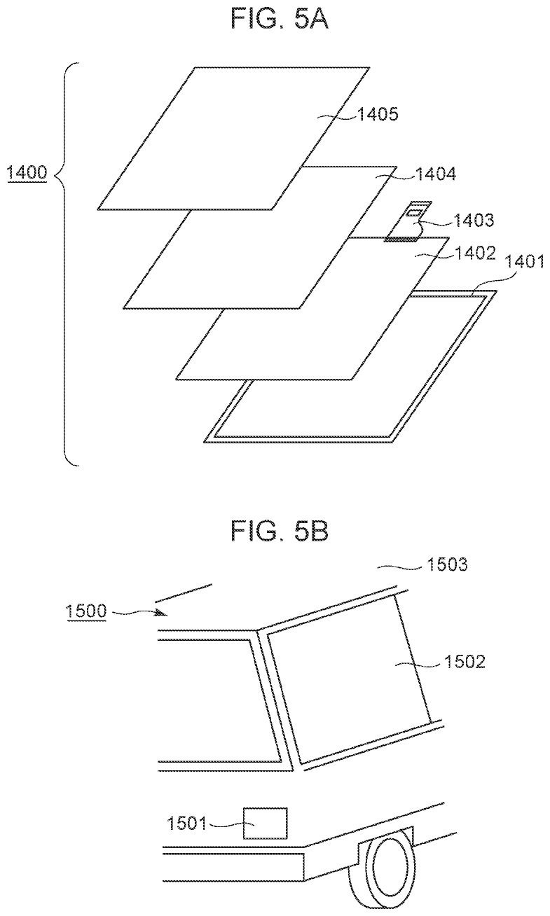

FIG. 5A is a schematic view illustrating an example of a lighting apparatus according to the present embodiment. A lighting apparatus 1400 may include a housing 1401, a light source 1402, a circuit board 1403, an optical film 1404, and a light diffusion unit 1405. The light source may include an organic light-emitting device according to the present embodiment. The optical film may be a film that improves the color rendering properties of the light source. The light diffusion unit can effectively diffuse light from the light source to deliver the light to a wide range when used for illumination and so forth. The optical film and the light diffusion unit may be disposed at the light emission side of the lighting apparatus. A cover may be disposed at the outermost portion, as needed.

The lighting apparatus is, for example, an apparatus that lights a room. The lighting apparatus may emit light of white, neutral white, or any color from blue to red. A light control circuit that controls the light may be provided.

The lighting apparatus may include the organic light-emitting device according to an embodiment of the present disclosure and a power supply circuit coupled thereto. The power supply circuit is a circuit that converts an AC voltage into a DC voltage. The color temperature of white is 4,200 K, and the color temperature of neutral white is 5,000 K. The lighting apparatus may include a color filter.

The lighting apparatus according to the present embodiment may include a heat dissipation unit. The heat dissipation unit is configured to release heat in the device to the outside of the device and is composed of, for example, a metal having a high specific heat and liquid silicone.

FIG. 5B is a schematic view illustrating an automobile as an example of a moving object according to the present embodiment. The automobile includes a tail lamp, which is an example of lighting units. An automobile 1500 includes a tail lamp 1501 and may be configured to light the tail lamp when a brake operation or the like is performed.

The tail lamp 1501 may include an organic light-emitting device according to the present embodiment. The tail lamp may include a protective member that protects the organic light-emitting device. The protective member may be composed of any transparent material having high strength to some extent and can be composed of, for example, polycarbonate. The polycarbonate may be mixed with, for example, a furandicarboxylic acid derivative or an acrylonitrile derivative.

The automobile 1500 may include an automobile body 1503 and windows 1502 attached thereto. The windows may be transparent displays if the windows are not used to check the front and back of the automobile. The transparent displays may include an organic light-emitting device according to the present embodiment. In this case, the components, such as the electrodes, of the organic light-emitting device are formed of transparent members.

The moving object according to the present embodiment may be, for example, a ship, an aircraft, or a drone. The moving object may include a body and a lighting unit attached to the body. The lighting unit may emit light to indicate the position of the body. The lighting unit includes the organic light-emitting device according to the present embodiment.

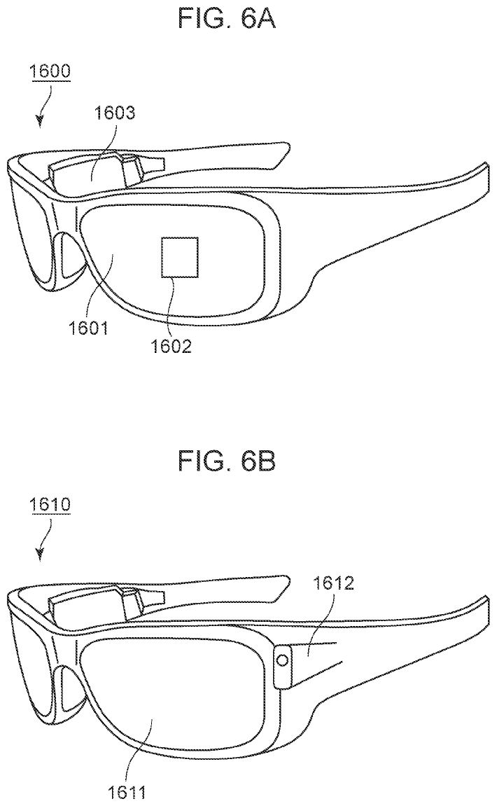

Examples of applications of the display apparatuses of the above embodiments will be described with reference to FIGS. 6A and 6B. The display apparatuses can be used for systems that can be worn as wearable devices, such as smart glasses, head-mounted displays (HMDs), and smart contacts. An image pickup and display apparatus used in such an example of the applications has an image pickup apparatus that can photoelectrically convert visible light and a display apparatus that can emit visible light.

FIG. 6A illustrates glasses 1600 (smart glasses) according to an example of applications. An image pickup apparatus 1602, such as a complementary metal-oxide semiconductor (CMOS) sensor or a single-photon avalanche diode (SPAD), is provided on a front side of a lens 1601 of the glasses 1600. The display apparatus according to any of the above-mentioned embodiments is provided on the back side of the lens 1601.

The glasses 1600 further include a control unit 1603. The control unit 1603 functions as a power source that supplies electric power to the image pickup apparatus 1602 and the display apparatus according to any of the embodiments. The control unit 1603 controls the operation of the image pickup apparatus 1602 and the display apparatus. The lens 1601 has an optical system for focusing light on the image pickup apparatus 1602.

FIG. 6B illustrates glasses 1610 (smart glasses) according to an example of applications. The glasses 1610 include a control unit 1612. The control unit 1612 includes an image pickup apparatus corresponding to the image pickup apparatus 1602 and a display apparatus. A lens 1611 is provided with the image pickup apparatus in the control unit 1612 and an optical system that projects light emitted from the display apparatus. An image is projected onto the lens 1611. The control unit 1612 functions as a power source that supplies electric power to the image pickup apparatus and the display apparatus and controls the operation of the image pickup apparatus and the display apparatus. The control unit may include a gaze detection unit that detects the gaze of a wearer. Infrared light may be used for gaze detection. An infrared light-emitting unit emits infrared light to an eyeball of a user who is gazing at a displayed image. An image of the eyeball is captured by detecting the reflected infrared light from the eyeball with an image pickup unit having light-receiving elements. The deterioration of image quality is reduced by providing a reduction unit configured to reduce light from the infrared light-emitting unit to the display unit when viewed in plan.

The user's gaze at the displayed image is detected from the image of the eyeball captured with the infrared light. Any known method can be used to the gaze detection using the captured image of the eyeball. As an example, a gaze detection method based on a Purkinje image of the reflection of irradiation light on a cornea can be used.

More specifically, the gaze detection process is based on a pupil-corneal reflection method. Using the pupil-corneal reflection method, the user's gaze is detected by calculating a gaze vector representing the direction (rotation angle) of the eyeball based on the image of the pupil and the Purkinje image contained in the captured image of the eyeball.

A display apparatus according to an embodiment of the present disclosure may include an image pickup apparatus including light-receiving elements, and may control an image displayed on the display apparatus based on the gaze information of the user from the image pickup apparatus.

Specifically, in the display apparatus, a first field-of-view area at which the user gazes and a second field-of-view area other than the first field-of-view area are determined on the basis of the gaze information. The first field-of-view area and the second field-of-view area may be determined by the control unit of the display apparatus or may be determined by receiving those determined by an external control unit. In the display area of the display apparatus, the display resolution of the first field-of-view area may be controlled to be higher than the display resolution of the second field-of-view area. That is, the resolution of the second field-of-view area may be lower than that of the first field-of-view area.

The display area includes a first display area and a second display area different from the first display area. Based on the gaze information, an area of higher priority is determined from the first display area and the second display area. The first display area and the second display area may be determined by the control unit of the display apparatus or may be determined by receiving those determined by an external control unit. The resolution of an area of higher priority may be controlled to be higher than the resolution of an area other than the area of higher priority. In other words, the resolution of an area of a relatively low priority may be low.

Artificial intelligence (AI) may be used to determine the first field-of-view area or the high-priority area. The AI may be a model configured to estimate the angle of gaze from the image of the eyeball and the distance to a target object located in the gaze direction, using the image of the eyeball and the actual direction of gaze of the eyeball in the image as teaching data. The AI program may be stored in the display apparatus, the image pickup apparatus, or an external apparatus. When the AI program is stored in the external apparatus, the AI program is transmitted to the display apparatus via communications.

In the case of controlling the display based on visual detection, smart glasses that further include an image pickup apparatus that captures an external image can be used. The smart glasses can display the captured external information in real time.

As described above, the use of an apparatus including the organic light-emitting device according to the present embodiment enables a stable display with good image quality even for a long time.

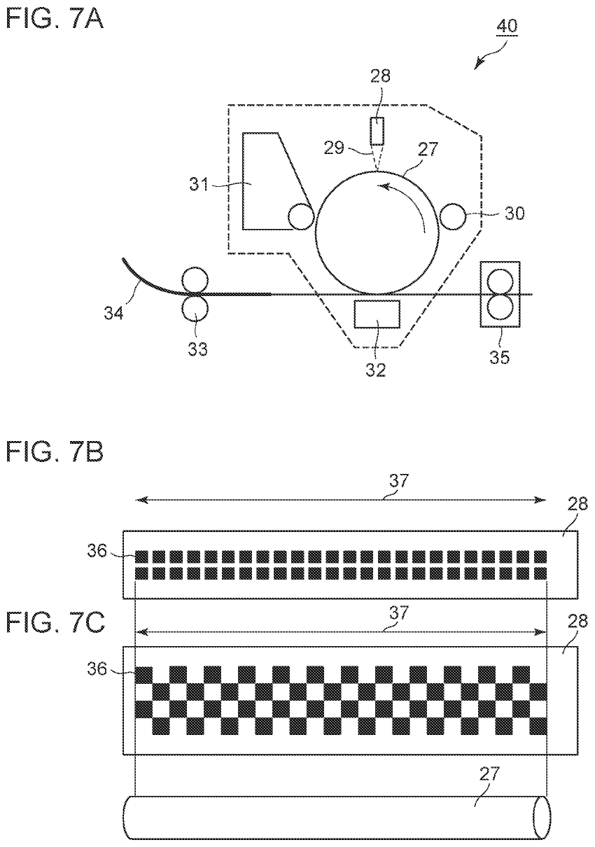

FIG. 7A is a schematic view of an example of an image-forming apparatus according to an embodiment of the present disclosure. An image-forming apparatus 40 is an electrophotographic image-forming apparatus and includes a photoconductor 27, an exposure light source 28, a charging unit 30, a developing unit 31, a transfer unit 32, a transport roller 33, and a fusing unit 35. The irradiation of light 29 is performed from the exposure light source 28 to form an electrostatic latent image on the surface of the photoconductor 27. The exposure light source 28 includes the organic light-emitting device according to the present embodiment. The developing unit 31 contains, for example, a toner. The charging unit 30 charges the photoconductor 27. The transfer unit 32 transfers the developed image to a recording medium 34. The transport roller 33 transports the recording medium 34. The recording medium 34 is paper, for example. The fusing unit 35 fixes the image formed on the recording medium 34.

FIGS. 7B and 7C each illustrate the exposure light source 28 and are each a schematic view illustrating multiple light-emitting portions 36 arranged on a long substrate. Arrows 37 each represent the row direction in which the organic light-emitting devices are arranged. The row direction is the same as the direction of the axis on which the photoconductor 27 rotates. This direction can also be referred to as the long-axis direction of the photoconductor 27. FIG. 7B illustrates a configuration in which the light-emitting portions 36 are arranged in the long-axis direction of the photoconductor 27. FIG. 7C is different from FIG. 7B in that the light-emitting portions 36 are arranged alternately in the row direction in a first row and a second row. The first row and the second row are located at different positions in the column direction. In the first row, the multiple light-emitting portions 36 are spaced apart. The second row has the light-emitting portions 36 at positions corresponding to the positions between the light-emitting portions 36 in the first row. In other words, the multiple light-emitting portions 36 are also spaced apart in the column direction. The arrangement in FIG. 7C can be rephrased as, for example, a lattice arrangement, a staggered arrangement, or a checkered pattern.

### EXAMPLES

While the present disclosure will be described below by examples, the present disclosure is not limited these examples.

### Example 1: Synthesis of Compound (1)

Compound (1) was synthesized by the following procedure.

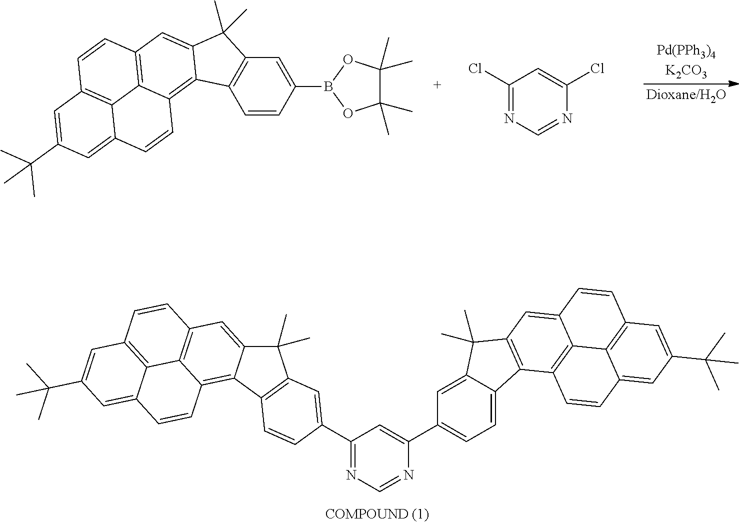 [SMILES: CC(C)(C)c1cc2ccc3cc4c(c5ccc(c1)c2c35)-c1ccc(B2OC(C)(C)C(C)(C)O2)cc1C4(C)C ; Clc1cc(Cl)ncn1 ; CC(C)(C)c1cc2ccc3cc4c(c5ccc(c1)c2c35)-c1ccc(-c2cc(-c3ccc5c(c3)C(C)(C)c3cc6ccc7cc(C(C)(C)C)cc8ccc(c3-5)c6c78)ncn2)cc1C4(C)C]

To a 50-mL recovery flask, 2-(2-(tert-butyl)-7,7-dimethyl-7H-indeno[1,2-a]pyren-9-yl)-4,4,5,5-tetramethyl-1,3,2-dioxaborolane (270 mg), 4,6-dichloropyrimidine (40 mg), tetrakis(triphenylphosphine)palladium (5 mg), potassium carbonate (177 mg), dioxane (10 mL), and water (5 mL) were added. The mixture was stirred at 90° C. for 10 hours. After extraction with dichloromethane, purification was performed by silica gel column chromatography. The resulting product was dispersed and washed with toluene (60 ml). The precipitated solid was collected by filtration and dried to give 138 mg of compound (1) as a yellow solid.

### Example 2: Synthesis of Compound (5)

Compound (5) was synthesized by the following procedure.

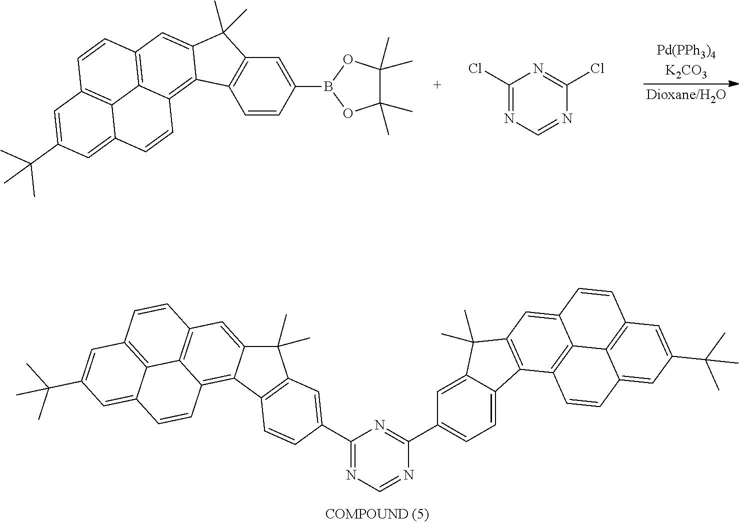 [SMILES: CC(C)(C)c1cc2ccc3cc4c(c5ccc(c1)c2c35)-c1ccc(B2OC(C)(C)C(C)(C)O2)cc1C4(C)C ; Clc1ncnc(Cl)n1 ; CC(C)(C)c1cc2ccc3cc4c(c5ccc(c1)c2c35)-c1ccc(-c2ncnc(-c3ccc5c(c3)C(C)(C)c3cc6ccc7cc(C(C)(C)C)cc8ccc(c3-5)c6c78)n2)cc1C4(C)C]

To a 50-mL recovery flask, 2-(2-(tert-butyl)-7,7-dimethyl-7H-indeno[1,2-a]pyren-9-yl)-4,4,5,5-tetramethyl-1,3,2-dioxaborolane (325 mg), 2,4-dichloro-1,3,5-triazine (46 mg), tetrakis(triphenylphosphine)palladium (6 mg), potassium carbonate (214 mg), dioxane (15 mL), and water (7.5 mL) were added. The mixture was stirred at 90° C. for 14 hours. After extraction with dichloromethane, purification was performed by silica gel column chromatography. The product was recrystallized in toluene (20 mL). The precipitated solid was collected by filtration and dried to give 100 mg of compound (5) as a yellow-green solid.

### Examples 4 to 6 and Comparative Example 1: Evaluation of Thermal Properties

The weight-loss initiation temperatures of compounds (1), (5), (10) and compound A, serving as a compound of a comparative example, under atmospheric pressure were measured with a thermogravimetry/differential thermal analyzer STA7200 (available from Hitachi High-Tech Science Corporation). In addition, the sublimation temperature was defined as the temperature at which the rate of weight loss under vacuum (2 Pa) reached 5% and was measured with a thermogravimetry/differential thermal analyzer TA7000 (available from Hitachi High-Tech Science Corporation). Table 1 presents the results.

TABLE 1

| | | Weight-loss initiation | Sublimation |
|---|---|---|---|
| | Compound | temperature/° C. | temperature/° C. |
| Example 4 | Compound | 450 | 385 |
| | (1) | | |
| Example 5 | Compound | 385 | 315 |
| | (5) | | |
| Example 6 | Compound | 260 | 205 |
| | (10) | | |
| Comparative | Compound A | 550 | 470 |
| example 1 | | | |

Table 1 indicates that each of the organic compounds represented by formula (1) successfully had a low weight-loss initiation temperature and a low sublimation temperature, compared with compound A of Comparative example 1. This is presumably due to the effect of using a nitrogen atom-containing heteroaryl group as Ar. From the above, it was found that the organic compound in which Ar is a substituted or unsubstituted heteroaryl group in formula (1) is an organic compound having excellent sublimability.

### Example 7 and Comparative Example 2: Evaluation of Organic Light-Emitting Device

In Example 7, an organic light-emitting device was produced by a method described below, the organic light-emitting device having the structure of anode/hole injection layer/hole transport layer/electron-blocking layer/light emitting layer/hole-blocking layer/electron transport layer/cathode sequentially disposed over a substrate, compound (1) being used as a guest in the light-emitting layer.

An ITO film, serving as an anode, having a thickness of 100 nm was formed on a glass substrate by a sputtering method, and the resulting substrate was used as a transparent conductive supporting substrate (ITO substrate). Organic compound layers and electrode layers described below were successively formed over the ITO substrate by vacuum deposition using resistance heating in a vacuum chamber with a pressure of 10⁻⁵ Pa. At this time, the formation was performed in such a manner that the electrode area was 3 mm².

TABLE 2

| | | | | Thick- |
|---|---|---|---|---|
| | | | | ness |
| | Material | | | (nm) |
| Metal electrode layer 2 | Al | | | 100 |
| Metal electrode layer 1 | Liq | | | 1 |
| Electron transport layer | ET14, Liq | | Ratio by | 10 |
| (ETL) | | | weight | |
| | | | ET14:Liq = | |
| | | | 80:20 | |
| Hole-blocking layer (HBL) | ET15 | | | 15 |
| Light-emitting layer (EML) | Host | EM33 | Ratio by | 10 |
| | Guest | Compound | weight | |
| | | (1) | EM33:(1) = | |
| | | | 99:1 | |

| | | |
|---|---|---|
| Electron-blocking layer | HT7 | 10 |
| (EBL) | | |
| Hole transport layer (HTL) | HT5 | 30 |
| Hole injection layer (HIL) | HT16 | 10 |

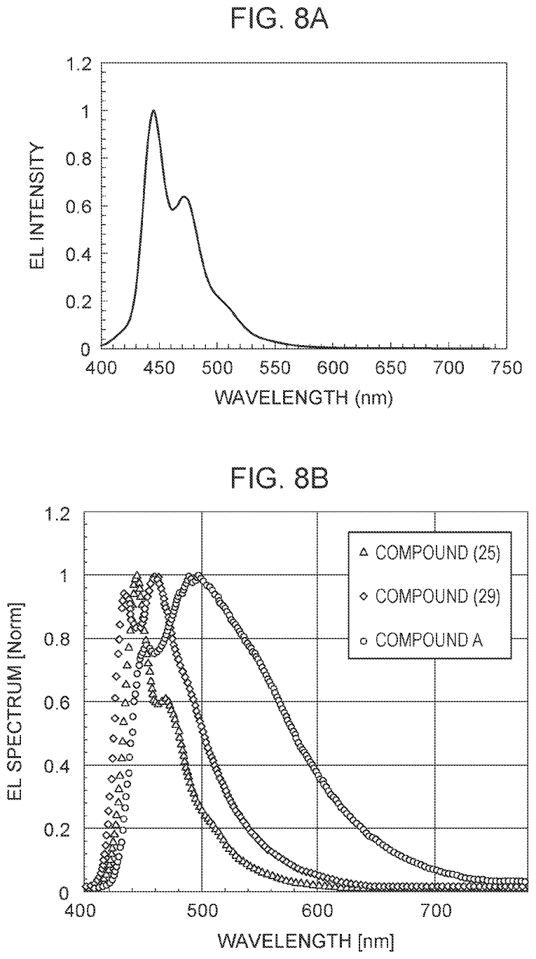

In order not to cause the deterioration of the organic light-emitting device due to moisture adsorption, the resulting structure was covered with a protective glass plate in a dry air atmosphere and sealed with an acrylic resin adhesive. As described above, an organic light-emitting device was produced. The resulting organic light-emitting device was subjected to current-voltage-luminance (IVL) measurement using the ITO electrode as an anode and the Al electrode as a cathode. FIG. 8A illustrates the normalized EL spectrum.

An organic light-emitting device of Comparative example 2 was produced in the same manner as in Example 7, except that the guest material was changed to compound A. The resulting device was subjected to IVL measurement in the same manner as in Example 7.

Table 3 presents the external quantum efficiencies (EQE) of the organic light-emitting devices of Example 7 and Comparative example 2 at 10 mA/cm², and the relative values (compound A was defined as 1) of the durability times (LT80) when the luminance reached 80% in continuous driving at 5 mA/cm², when the initial values of the luminance of the organic light-emitting devices at 5 mA/cm² were 100%.

TABLE 3

| | Compound | EQE/% | LT80/hr |
|---|---|---|---|
| Example 7 | compound (1) | 5.48 | 1.3 |
| Comparative example 2 | compound A | 5.03 | 1 |

Table 3 indicates that the organic compound in which Ar was a substituted or unsubstituted heteroaryl group in formula (1) exhibited superior external quantum efficiency and device lifetime to those of the compound A of the comparative example.

### Example 8

### Synthesis of Compound (25)

Compound (25) was synthesized by the following procedure.

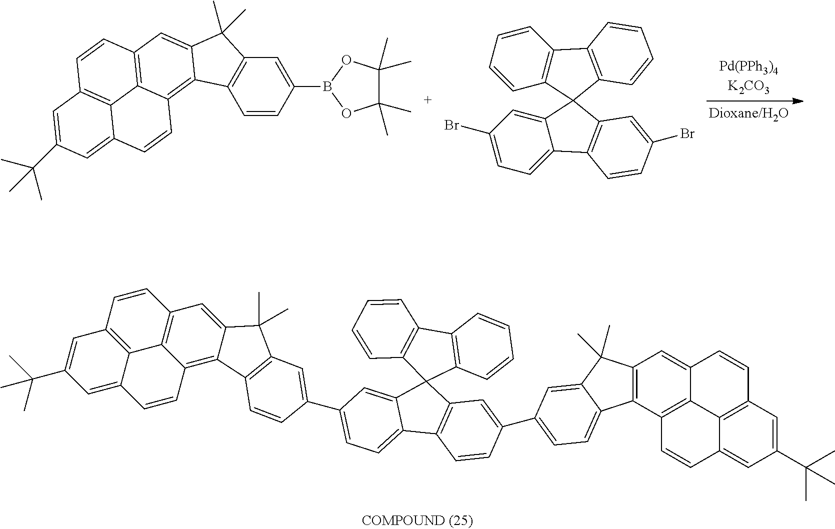

To a 50-mL recovery flask, 2-(2-(tert-butyl)-7,7-dimethyl-7H-indeno[1,2-a]pyren-9-yl)-4,4,5,5-tetramethyl-1,3,2-dioxaborolane (280 mg), 2,7-dibromo-9,9′-spirobi[fluorene] (126 mg), tetrakis(triphenylphosphine)palladium (9 mg), potassium carbonate (147 mg), dioxane (10 mL), and water (5 mL) were added. The mixture was stirred at 90° C. for 10 hours. After extraction with dichloromethane, purification was performed by gel permeation chromatography, thereby providing 60 mg of compound (1) as a yellow solid.

### Example 9

### Synthesis of Compound (29)

Compound (29) was synthesized by the following procedure.

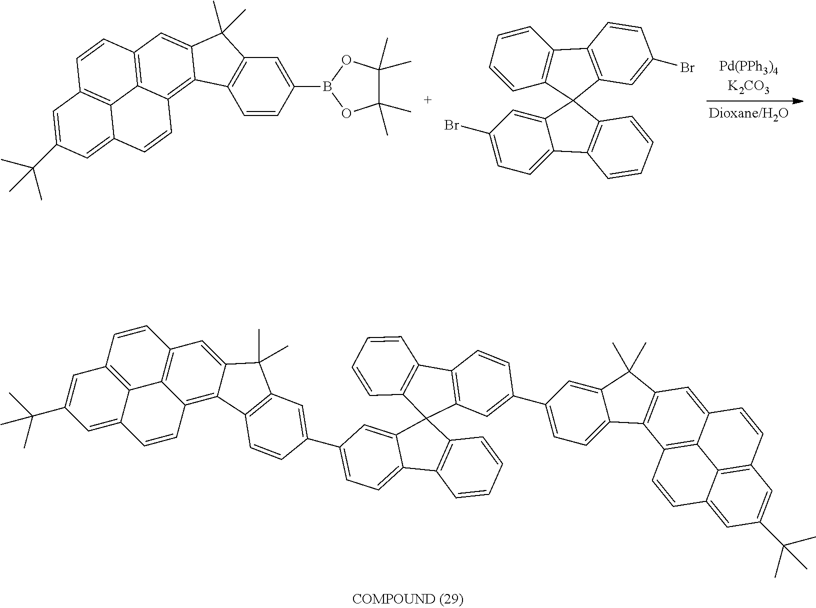

To a 50-mL recovery flask, 2-(2-(tert-butyl)-7,7-dimethyl-7H-indeno[1,2-a]pyren-9-yl)-4,4,5,5-tetramethyl-1,3,2-dioxaborolane (280 mg), 2,2′-dibromo-9,9′-spirobi[fluorene] (126 mg), tetrakis(triphenylphosphine)palladium (9 mg), potassium carbonate (147 mg), dioxane (10 mL), and water (5 mL) were added. The mixture was stirred at 90° C. for 10 hours.

After extraction with dichloromethane, purification was performed by gel permeation chromatography, thereby providing 50 mg of compound (29) as a yellow solid.

### Examples 10 and 11 and Comparative Example 3

### Evaluation of Solubility

First, 50 mg of compound (25), 50 mg of compound (29), which were synthesized in the above examples, and 50 mg of compound A as a comparative example were placed in respective sample bottles each containing 1 mL of toluene. The mixtures were stirred at room temperature to determine whether the compounds were dissolved. Table 4 presents the results. In Table 4, A indicates that the compound was dissolved in the solvent, and B indicates that the compound was not easily dissolved in the solvent and that it was visually observed that the compound remained in the solution.

TABLE 4

| | Compound | Solubility |
|---|---|---|
| Example 10 | compound (25) | A |
| Example 11 | compound (29) | A |
| Comparative example 3 | compound A | B |

It was found from Table 4 that compounds (25) and (29) according to embodiments of the present disclosure had improved solubility, compared with Comparative example 3. From the above, it was found that the organic compound in which Ar was a spirofluorene skeleton was an organic compound having excellent solubility.

### Example 12: PL Spectrum in Solution

Compounds (25) and (29) and compound A as a comparative example were separately dissolved in toluene to prepare solutions having a concentration of 10⁻⁵ mol/L, and the wavelengths of the peak maxima of the PL spectra of the resulting solutions were measured.

### Examples 13 and 14 and Comparative Example 4 (Evaluation of Organic Light-Emitting Devices)

In Example 13, an organic light-emitting device was produced by a method described below, the organic light-emitting device having the structure of anode/hole injection layer/hole transport layer/electron-blocking layer/light emitting layer/hole-blocking layer/electron transport layer/cathode sequentially disposed over a substrate, compound (25) being used as a guest compound for the light-emitting layer.

An ITO film, serving as an anode, having a thickness of 100 nm was formed on a glass substrate by a sputtering method, and the resulting substrate was used as a transparent conductive supporting substrate (ITO substrate). The glass substrate with the ITO film was subjected to ultrasonic cleaning successively with acetone and isopropyl alcohol (IPA), washed with boiling IPA, and dried. Subsequently, the glass substrate was subjected to UV-ozone cleaning. The glass substrate treated in this manner was used as a transparent conductive supporting substrate.

PEDOT:PSS (trade name: CLEVIOS™ P VP AI 4083) was deposited as a hole transport layer by a spin coating method. The film thickness of the hole injection-transport layer was 70 nm.

A toluene solution of compound (25):EM33 (concentration: 1.0% by weight, compound (25):EM33=1:99) was prepared for a light-emitting layer. This solution was then formed into a film on the hole injection-transport layer by a spin coating method. The film thickness of the light-emitting layer was 20 nm.

A hole-blocking (HB) layer, an electron transport layer, and metal electrode layers were successively formed on the light-emitting layer by vacuum deposition using resistance heating in a vacuum chamber with a pressure of 10⁻⁵ Pa. At this time, the formation was performed in such a manner that the electrode area was 3 mm². The layer structure is described below.

TABLE 5

| | | | | Thick- |
|---|---|---|---|---|
| | | | | ness |
| | Material | | | (nm) |
| Metal electrode layer 2 | Al | | | 100 |
| Metal electrode layer 1 | Liq | | | 1 |
| Electron transport layer | ET14, Liq | | Ratio by | 10 |
| (ETL) | | | weight | |
| | | | ET14:Liq = | |
| | | | 80:20 | |
| Hole-blocking layer (HBL) | ET15 | | | 10 |
| Light-emitting layer (EML) | Host | EM33 | Ratio by | 20 |
| | Guest | Compound | weight | |
| | | (25) | EM33:(25) = | |
| | | | 99:1 | |

| | | |
|---|---|---|
| Hole transport layer (HTL) | PEDOT:PSS | 70 |

In order not to cause the deterioration of the organic light-emitting device due to moisture adsorption, the resulting structure was covered with a protective glass plate in a dry air atmosphere and sealed with an acrylic resin adhesive. As described above, an organic light-emitting device was produced. The resulting organic light-emitting device was subjected to EL spectrum measurement using the ITO electrode as an anode and the Al electrode as a cathode.

An organic light-emitting device of Example 14 was produced in the same manner as in Example 13, except that the guest compound was changed to compound (29). The EL spectrum of the resulting device was measured in the same manner as in Example 13.

An organic light-emitting device of Comparative example 4 was produced in the same manner as in Example 13, except that the guest compound was changed to compound A. The EL spectrum of the resulting device was measured in the same manner as in Example 13.

FIG. 8B illustrates normalized EL spectra obtained in Examples 13 and 14 and Comparative example 4.

A change in the wavelength of the first peak maximum between each of the obtained EL spectra and a corresponding one of the PL spectra in the solutions measured in Example 12 was calculated. The full width at half maximum in each EL spectrum was measured. Table 6 presents the results.

TABLE 6

| | | Change in wavelength of | Full width |
|---|---|---|---|
| | | first peak maximum in | at half |
| | Compound | solution and device/nm | maximum/nm |
| Example 13 | Compound | <1 | 47 |
| | (25) | | |
| Example 14 | Compound | 6 | 75 |
| | (29) | | |
| Comparative | Compound | 48 | 140 |
| example 4 | A | | |

It was found from Table 6 that each of compounds (25) and (29) according to embodiments of the present disclosure had a small change in the emission wavelength of the first peak maximum between the solution and the device and a small full width at half maximum, compared with compound A of Comparative example.

In formula (1), when Ar is a spirofluorene-containing skeleton, the organic compound according to an embodiment of the present disclosure has a bulky skeleton, so that it is considered that intermolecular stacking can be inhibited. For this reason, the full width at half maximum at the absorption wavelength was considered to be successfully narrowed.

As described above, according to an embodiment of the present disclosure, it is possible to provide the organic compound and the organic light-emitting device having excellent light emission characteristics. Specifically, the organic compound having excellent sublimability or solubility can be provided. Thus, it is possible to provide the organic light-emitting device excellent in luminous efficiency or device lifetime. In addition, it is possible to provide the organic light-emitting device having excellent color purity with little color change in the emission color between the solution and the organic light-emitting device.

According to an embodiment of the present disclosure, it is possible to provide the organic compound having excellent light emission characteristics.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-093763, filed Jun. 9, 2022, which is hereby incorporated by reference herein in its entirety.

What is claimed is:

1. An organic compound represented by formula (1):
Ip-L¹-Ar-L²-FL (1)
where in formula (1), Ip is an indenopyrene-containing skeleton, Ar is a substituted or unsubstituted heteroaryl group or a spirofluorene-containing skeleton, FL is an indenopyrene skeleton or a skeleton having a structure represented by formula (2), and L¹ and L² are each independently selected from the group consisting of a direct bond and a substituted or unsubstituted arylene group: 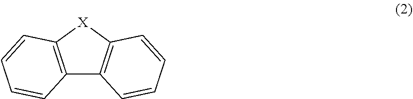
where in formula (2), X is an oxygen atom, a sulfur atom, a nitrogen atom, CR¹R², or NR³, where R¹ to R³ are each independently selected from the group consisting of a hydrogen atom, a deuterium atom, a halogen atom, a substituted or unsubstituted alkyl group, a substituted or unsubstituted aryl group, and a substituted or unsubstituted heteroaryl group.

2. The organic compound according to claim 1, wherein in formula (1), Ip contains a 7H-indeno[1,2-a]pyrene skeleton.

3. The organic compound according to claim 1, wherein in formula (1), FL contains an indenopyrene skeleton or a fluorene skeleton.

4. The organic compound according to claim 1, wherein formula (1), Ar is a nitrogen atom-containing heteroaryl group.

5. The organic compound according to claim 4, wherein in formula (1), Ar contains at least one skeleton selected from the group consisting of a pyridine skeleton, a pyrimidine skeleton, a pyrazine skeleton, a pyridazine skeleton, a triazine skeleton, a quinoline skeleton, an isoquinoline skeleton, and a naphthyridine skeleton.

6. The organic compound according to claim 5, wherein in formula (1), Ar contains at least one skeleton selected from the group consisting of a pyridine skeleton, a pyrimidine skeleton, and a triazine skeleton.

7. The organic compound according to claim 1, wherein in formula (1), Ar is a 9,9′-spirobifluorene skeleton.

8. The organic compound according to claim 1, wherein in formula (1), Ip contains an alkyl group having 1 to 4 carbon atoms.

9. The organic compound according to claim 8, wherein in formula (1), Ip contains a methyl group or a tert-butyl group.

10. The organic compound according to claim 1, wherein in formula (1), FL contains an alkyl group having 1 to 4 carbon atoms or an aryl group having 6 to 10 carbon atoms.

11. The organic compound according to claim 10, wherein in formula (1), FL contains a methyl group or a tert-butyl group.

12. The organic compound according to claim 1, wherein in formula (1), Ar contains an alkyl group having 1 to 4 carbon atoms.

13. The organic compound according to claim 12, wherein in formula (1), Ar contains a tert-butyl group.

14. An organic light-emitting device, comprising:
a first electrode;
a second electrode; and
an organic compound layer disposed between the first electrode and the second electrode,
wherein the organic compound layer contains the organic compound according to claim 1.

15. The organic light-emitting device according to claim 14, wherein the organic compound layer contains a light-emitting layer, and
the light-emitting layer contains the organic compound.

16. The organic light-emitting device according to claim 15, wherein the light-emitting layer further contains a first compound, and
the first compound is a compound having a higher lowest excited singlet energy than the organic compound.

17. The organic light-emitting device according to claim 16, wherein the first compound is a hydrocarbon compound.

18. The light-emitting device according to claim 16, wherein the light-emitting layer further contains a second compound, and
the second compound is a compound having a higher lowest excited singlet energy than the organic compound.

19. A display apparatus, comprising:
multiple pixels,
at least one of the multiple pixels including:
the organic light-emitting device according to claim 14, and
a transistor coupled to the organic light-emitting device.

20. A photoelectric conversion apparatus, comprising:
an optical unit including multiple lenses;
an image pickup device configured to receive light passing through the optical unit; and
a display unit configured to display an image captured by the image pickup device,
wherein the display unit includes the organic light-emitting device according to claim 14.

21. An electronic apparatus, comprising:
a display unit including the organic light-emitting device according to claim 14;
a housing provided with the display unit; and
a communication unit being disposed in the housing and communicating with an outside.

22. A lighting apparatus, comprising:
a light source including the organic light-emitting device according to claim 14; and
a light diffusion unit or an optical film configured to transmit light emitted from the light source.

23. A moving object, comprising:
a lighting unit including the organic light-emitting device according to claim 14; and
a body provided with the lighting unit.

24. An image-forming apparatus, comprising:
a photoconductor; and
an exposure light source configured to expose the photoconductor,
wherein the exposure light source includes the organic light-emitting device according to claim 14.
